(19) United States
(12) Patent Application Publication
(10) Pub. No.: US 2006/0001081 A1
(43) Pub. Date: Jan. 5, 2006

(54) Nonvolatile semiconductor memory device and manufacturing method thereof

(75) Inventors: Yoshitaka Sasago, Tachikawa (JP); Takashi Kobayashi, Tokorozawa (JP); Naohiro Hosoda, Hitachinaka (JP); Tetsuo Adachi, Hitachinaka (JP); Masataka Kato, Abiko (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 11/166,114

(22) Filed: Jun. 27, 2005

(30) Foreign Application Priority Data
Jul. 2, 2004 (JP) 2004-196825

(51) Int. Cl. H01L 29/788

(52) U.S. Cl. 257/316

(57) ABSTRACT

A leakage current flowing between data lines of a nonvolatile semiconductor memory is reduced. In a memory array of a nonvolatile semiconductor memory device having an AND type flash memory, a concave portion is formed in a junction isolation area between adjacent word limes and between adjacent assist gate wirings AGL, and the height of a main surface (first main surface) of a semiconductor substrate in the region where the concave portion is formed is made lower than that of the main surface (second main surface) of the semiconductor substrate to which an assist gate wiring is facing. As a result, it is possible to control the leakage current that flows between the drain line and source line in the aforementioned junction isolation region during operation of a flash memory.

### CLAIM OF PRIORITY

The present application claims priority from Japanese application JP 2004-196825 filed on Jul. 2, 2004, the content of which is hereby incorporated by reference into this application.

### FIELD OF THE INVENTION

The present invention relates to the field of nonvolatile semiconductor memory devices and manufacturing methods thereof, and more particularly to an improved method for nonvolatile semiconductor memory devices having a nonvolatile memory which can be programmed/erased electrically and manufacturing methods thereof.

### BACKGROUND OF THE INVENTION

A so-called flash memory is known as one for which bulk erasing is possible in nonvolatile semiconductor memory devices having a nonvolatile memory in which electric programming/erasing is possible. Because flash memory is easy to carry, has excellent shock resistance, and electric bulk erasing is possible, it has seen a rapidly increasing demand in these days as a memory device for personal digital assistants such as mobile personal computers and digital still cameras. In order to expand the market, a reduction in bit cost by a drastic decrease in the memory cell area is an important subject. On the other hand, high-speed programming becomes a new demand for a flash memory with rapid growth in the market for the purpose of content distribution.

In such a background, recently, technology has been reported in which the memory cell area is 4F² (herein, F is a design rule) which is a physical limitation (International Electron Devices Meeting, 2003, pp. 819-822 and International Electron Devices Meeting, 2003, pp. 823-826), and it is expected that further progress of bit cost reduction is possible. However, in the method according to FN (Fowler-Nordheim) tunnel currents which has been used for a conventional high density flash, it is said that speed enhancement of programming has a limitation, and a breakthrough is necessary. International Electron Devices Meeting, 2003, pp. 823-826 discloses a cell in which a stripe-shaped assist gate formed on a silicon substrate through a gate oxide film is provided besides a floating gate and a control gate. An inversion layer formed on a silicon substrate by applying a voltage to this assist gate is used for a common source line/drain line, thereby, a diffusion layer which used to be necessary is removed, and the memory cell is made finer, and high-speed programming is achieved by using source side hot electrons. Moreover, a technology to solve two big subjects required of next generation high density flash, which are drastic reduction in bit cost and speed-up in programming, are reported in this document.

Furthermore, for instance, JP-A No. 338183/2003 discloses a nonvolatile memory having an assist gate which controls the programming current flowing between a source and a drain of a memory call.

However, the inventors found that the following new problems were caused when the reduction in memory call size of an AND type flash memory progressed since the 90 nm generation.

Specifically, in an AND type flash memory, gate electrodes are arranged between mutually adjacent word lines and not arranged between a drain line and a source line, and an active region (junction isolation region) is formed in which an isolation region such as a field insulation film and an STI (Shallow Trench Isolation), etc. is not arranged. However, there is a problem that leakage current flows between a drain line and a source line in the above-mentioned active region during an operation such as programming/reading data of a flash memory, thereby, the leakage current flowing between the bit lines increases. As a result, there is a problem that the yield of flash memory decreases caused by generating bit defects.

Especially, in a flash memory which has a configuration disclosed in the above-mentioned non-patent document 2, an inversion layer is formed on the semiconductor substrate by applying a voltage to the assist gate while programming and reading, this being used as source line/drain lines. However, it is necessary to apply a high voltage to the assist gate to make the electric resistance of the invasion layer equal to that of the diffusion layer, so that the inversion layer grows not only right under the assist gate, but even outside of it. Therefore, if the distance between the mutually adjacent assist gates becomes smaller, the distance between the mutually adjacent inversion layers becomes even smaller. Thereby, the leakage current flowing between the source line/drain lines abruptly increases in the region of space between the assist gates and the space between the word lines, and neither programming nor reading operations can be performed. Therefore, since the 90 nm generation, a reduction in bit cost and high-speed programming have not been compatible.

Moreover, although the chip size can be reduced when the number of memory cells which can connect with one bit line increases, the number of connecting memory cell is limited by the value of the leakage current between the above-mentioned source line/drain line, so that there is also a problem that an increase in the leakage current prevents an increase of the number of connecting memory cells and a reduction in the chip size. Furthermore, since the issue of an increase of the leakage current becomes serious with reducing the gate length of the memory cell, it also becomes an impediment to the reduction in the gate length of the memory cell, so that problem arises that it prevents the improvement of integration (that is, an increase of the capacity of the memory chip) and a reduction in the chip size.

### SUMMARY OF THE INVENTION

It is the objective of the present invention to provide a technique for reducing the leakage current between data lines of a nonvolatile semiconductor memory device.

The aforementioned and other objectives and new features of the present invention will be more clearly understood from the following descriptions and accompanying drawings of these detailed descriptions.

The following is a brief description of a typical embodiment disclosed in the present invention.

Specifically, the present invention is one where the height of the main surface of a semiconductor substrate on which a first gate electrode (assist gate electrode) and a second gate electrode (control gate electrode) are not provided is made lower than the main surface of the aforementioned semiconductor substrate on which a first gate electrode is provided.

Moreover, the present invention is one where the height of the main surface of a semiconductor substrate in the region located between the adjacent plurality of first gate electrodes (assist gate electrode) and the adjacent plurality of second gate electrodes (control gate electrode) intersecting the aforementioned plurality of first gate electrodes is made different than the height of the main surface of the aforementioned semiconductor substrate to which is facing the aforementioned first gate electrodes.

The following is a brief description of a typical embodiment disclosed in the present invention.

That is, it is possible to reduce the leakage current between the data lines of a nonvolatile semiconductor memory device by making the height of the semiconductor substrate, on which a first gate electrode (assist gate electrode) and a second gate electrode (control gate electrode), are not provided lower than that of the aforementioned semiconductor substrate, on which the first gate electrode is provided.

### BRIEF DESCRIPTION OF THE DRAWINGS

FIG. 1 is a circuit drawing schematically illustrating a circuit part of a memory array of the nonvolatile semiconductor memory device described in the first embodiment.

FIG. 2 is a main plane drawing illustrating a memory array a nonvolatile semiconductor memory device shown in FIG. 1.

FIG. 3 is a cross-sectional drawing at the position of line X1-X1 in FIG. 2.

FIG. 4 is a cross-sectional drawing at the position of line X2-X2 in FIG. 2.

FIG. 5 is a cross-sectional drawing at the position of line Y1-Y1 in FIG. 2.

FIG. 6 is a cross-sectional drawing at the position of line Y2-Y2 in FIG. 2.

FIG. 7 is an enlarged cross-sectional drawing at the position of line Y3-Y3 in FIG. 2.

FIG. 8 is a main plane drawing illustrating a memory array of a nonvolatile semiconductor memory device that the inventors discussed.

FIG. 9 is a cross-sectional drawing at the position of line X1-X1 in FIG. 8 in the cases of data programming and reading operations.

FIG. 10 is a cross-sectional drawing at the position of line X2-X2 in FIG. 8 in the cases of data programming and reading operations.

FIG. 11 is a main plane circuit drawing illustrating a memory array of a nonvolatile semiconductor memory device shown in FIG. 1 in the case of a data reading operation.

FIG. 12 is a cross-sectional drawing of a nonvolatile semiconductor memory device shown in FIG. 1 at the position of line X1-X1 in FIG. 2 in the case of a data reading operation.

FIG. 13 is a cross-sectional drawing of a nonvolatile semiconductor memory device shown in FIG. 1 at the position of line X2-X2 in FIG. 2 in the case of a data reading operation.

FIG. 14 is a main plane circuit drawing illustrating a memory array of a nonvolatile semiconductor memory device shown in FIG. 1 in the case of a data programming operation.

FIG. 15 is a cross-sectional drawing of a nonvolatile semiconductor memory device shown in FIG. 1 at the position of line X1-X1 in FIG. 2 in the case of a data programming operation.

FIG. 16 is a cross-sectional drawing of a nonvolatile semiconductor memory device shown in FIG. 1 at the point of line X2-X2 in FIG. 2 in the case of a data programming operation.

FIG. 17 is a viewgraph showing a relationship between a process rule and a leakage current in the case of a data reading operation.

FIG. 18 is a viewgraph showing a relationship between a process rule and a leakage current in the case of a data programming operation.

FIG. 19 is main cross-sectional drawings of a semiconductor substrate during a manufacturing process of a nonvolatile semiconductor memory device shown in FIGS. 1 to 7.

FIG. 20 is main cross-sectional drawings of a semiconductor substrate during a manufacturing process of a nonvolatile semiconductor memory device following FIG. 19.

FIG. 21 is main cross-sectional drawings of a semiconductor substrate during a manufacturing process of a nonvolatile semiconductor memory device following FIG. 20.

FIG. 22 is main cross-sectional drawings of a semiconductor substrate during a manufacturing process of a nonvolatile semiconductor memory device following FIG. 21.

FIG. 23 is main cross-sectional drawings of a semiconductor substrate during a manufacturing process of a nonvolatile semiconductor memory device following FIG. 22.

FIG. 24 is main cross-sectional drawings of a semiconductor substrate during a manufacturing process of a nonvolatile semiconductor memory device following FIG. 23.

FIG. 25 is main cross-sectional drawings of a semiconductor substrate during a manufacturing process of a nonvolatile semiconductor memory device following FIG. 24.

FIG. 26 is main cross-sectional drawings of a semiconductor substrate during a manufacturing process of a nonvolatile semiconductor memory device following FIG. 25.

FIG. 27 is main cross-sectional drawings of a semiconductor substrate during a manufacturing process of a nonvolatile semiconductor memory device following FIG. 26.

FIG. 28 is main cross-sectional drawings of a semiconductor substrate during a manufacturing process of a nonvolatile semiconductor memory device following FIG. 27.

FIG. 29 is main cross-sectional drawings of a semiconductor substrate during a manufacturing process of a nonvolatile semiconductor memory device following FIG. 28.

FIG. 30 is main cross-sectional drawings of a semiconductor substrate during a manufacturing process of a nonvolatile semiconductor memory device following FIG. 29.

FIG. 31 is main cross-sectional drawings of a semiconductor substrate during a manufacturing process of a nonvolatile semiconductor memory device following FIG. 30.

FIG. 32 is main cross-sectional drawings of a semiconductor substrate during a manufacturing process of a nonvolatile semiconductor memory device following FIG. 31.

FIG. 33 is main cross-sectional drawings of a semiconductor substrate during a manufacturing process of a nonvolatile semiconductor memory device of another embodiment of the present invention.

FIG. 34 is main cross-sectional drawings of a semiconductor substrate during a manufacturing process of a nonvolatile semiconductor memory device following FIG. 33.

FIG. 35 is main cross-sectional drawings of a semiconductor substrate during a manufacturing process of a nonvolatile semiconductor memory device following FIG. 34.

FIG. 36 is main cross-sectional drawings of a semiconductor substrate during a manufacturing process of a nonvolatile semiconductor memory device following FIG. 35.

FIG. 37 is main cross-sectional drawings of a semiconductor substrate during a manufacturing process of a nonvolatile semiconductor memory device following FIG. 35, and is cross-sectional drawings at the positions of line X1-X1, line X2-X2, line Y1-Y1, and line Y2-Y2 of FIG. 36.

FIG. 38 is main cross-sectional drawings of a semiconductor substrate during a manufacturing process of a nonvolatile semiconductor memory device following FIG. 37.

FIG. 39 is main cross-sectional drawings of a semiconductor substrate during a manufacturing process of a nonvolatile semiconductor memory device following FIG. 38.

FIG. 40 is main cross-sectional drawings of a semiconductor substrate during a manufacturing process of a nonvolatile semiconductor memory device following FIG. 39.

FIG. 41 is main cross-sectional drawings of a semiconductor substrate during a manufacturing process of a nonvolatile semiconductor memory device following FIG. 40.

FIG. 42 is main cross-sectional drawings of a semiconductor substrate during a manufacturing process of a nonvolatile semiconductor memory device following FIG. 41.

FIG. 43 is main cross-sectional drawings of a semiconductor substrate during a manufacturing process of a nonvolatile semiconductor memory device following FIG. 42.

FIG. 44 is a main circuit drawing illustrating a memory array of a nonvolatile semiconductor memory device of yet another embodiment of the present invention.

FIG. 45 is a main plane drawing illustrating a memory array of a nonvolatile semiconductor memory device of FIG. 44.

FIG. 46 is a cross-sectional drawing at the position of line X3-X3 in FIG. 45.

FIG. 47 is a cross-sectional drawing at the position of line X4-X4 in FIG. 45.

FIG. 48 is a cross-sectional drawing at the position of line Y4-Y4 in FIG. 45.

FIG. 49 is a cross-sectional drawing at the position of line Y5-Y5 in FIG. 45.

FIG. 50 is a main plane drawing illustrating a memory array of a nonvolatile semiconductor memory device that the inventors discussed.

FIG. 51 is a cross-sectional drawing at the position of line X3-X3 in FIG. 50 in the case of data programming and reading operations.

FIG. 52 is a cross-sectional drawing at the position of line X4-X4 in FIG. 50 in the case of data programming and reading operations.

FIG. 53 is a main plane circuit drawing illustrating an example of a case of a data programming operation of a nonvolatile semiconductor memory device shown in FIG. 44.

FIG. 54 is a main plane circuit drawing illustrating an example of a case of a data erasing operation of a nonvolatile semiconductor memory device shown in FIG. 44.

FIG. 55 is a main plane circuit drawing illustrating an example of a case of a data reading operation of a nonvolatile semiconductor memory device shown in FIG. 44.

FIG. 56 is main cross-sectional drawings of a semiconductor substrate during a manufacturing process of a nonvolatile semiconductor memory device shown in FIG. 45, etc.

FIG. 57 is main cross-sectional drawings of a semiconductor substrate during a manufacturing process of a nonvolatile semiconductor memory device following FIG. 56.

FIG. 58 is main cross-sectional drawings of a semiconductor substrate during a manufacturing process of a nonvolatile semiconductor memory device following FIG. 57.

FIG. 59 is main cross-sectional drawings of a semiconductor substrate during a manufacturing process of a nonvolatile semiconductor memory device following FIG. 58.

### DETAILED DESCRIPTION OF THE DRAWINGS

The following embodiment will be described separately in a plurality of sections or embodiments when it is necessary for convenience. However, except for the case specifically described, these are not unrelated to each other and they bear a relationship where one is a part of another or all of modified embodiments, details, and additional descriptions, etc. Moreover, in the case when the number of factors, etc. (including the number, value, quantity, and range, etc.) is mentioned in the following embodiments, it is to be understood that the invention is not intended to be limited to the specific number and it may be the specific number or more or less, except for the case when it is specifically described and the number is principally limited clearly. Furthermore, in the following embodiments, it is understood that the components (including element step, etc.) are not always essential, except for the case when it is specifically described or principally obviously essential. Similarly, when the invention describes the shapes of components and the positional relationship in the following embodiments, it is understood that one which is practically approximate or similar in shape, etc. is included except for the case when it is specifically described or not principally different. This is similar in the aforementioned values and ranges. Moreover, in all the drawings to describe the embodiments, like reference symbols designate corresponding functions in several drawings and the repetition of the description is omitted. The following is a detailed description of the embodiments of the present invention with reference to the accompanying drawings.

### First Embodiment

A nonvolatile semiconductor memory device described in this first embodiment is, for instance, a 4 Gb (gigabit) AND type flash memory having an assist gate structure used for a storage medium of various portable devices, information devices and telecommunications devices such as, for instance, mobile personal computers, digital still cameras, portable music players, digital video cameras, PDA (Personal Digital Assistants), and portable telephones, etc.

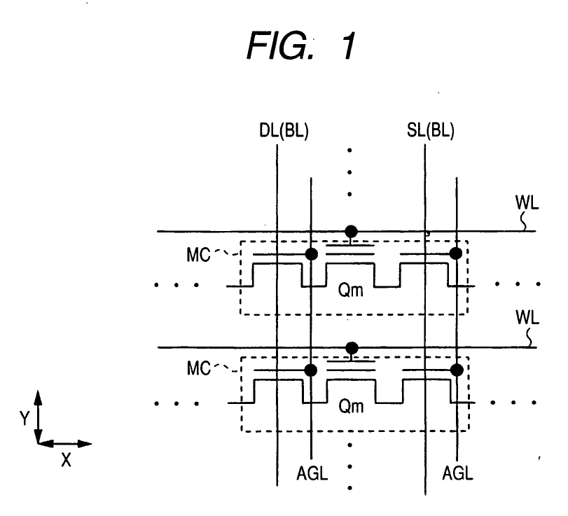

FIG. 1 is a schematic drawing illustrating a main circuit diagram of a memory array of a flash memory described in the first embodiment. Herein, the symbol Y designates the first direction and the symbol X designates the second direction intersecting the first direction.

A plurality of nonvolatile memory cells (hereinafter, it is simply called a memory cell) MC are arranged in a matrix fashion in the memory array. Each memory cell MC is connected in parallel between the mutually adjacent local data lines BL (drain line DL and source line SL). However, the drain line DL and the source line SL are not formed on the semiconductor substrate (hereinafter, it is simply called substrate) from the beginning as described later, but it is formed with the inversion layer created in the substrate that the assist gate wiring AGL faces by applying a desired voltage to the assist gate wiring (first gate electrode) while programming and reading information.

Each memory cell MC has the memory MIS•FETQm which contributes information storage. The memory MIS•FETQm has the control gate (second gate electrode) and the floating gate electrode (third gate electrode). The control gate electrode of the memory MIS•FETQm is formed with a part of the word line WL. Each word line WL is connected electrically with control gate electrodes of a plurality of memory MIS•FETQm arranged along the second direction X. The aforementioned floating gate electrode is an electrode in which charges are accumulated contributing to information storage.

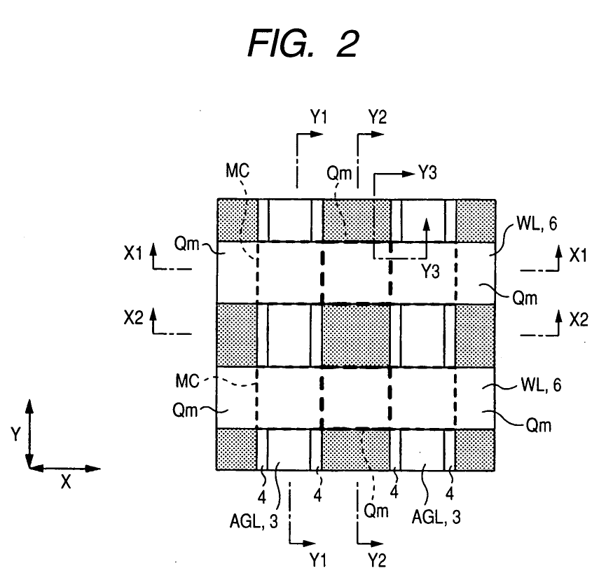

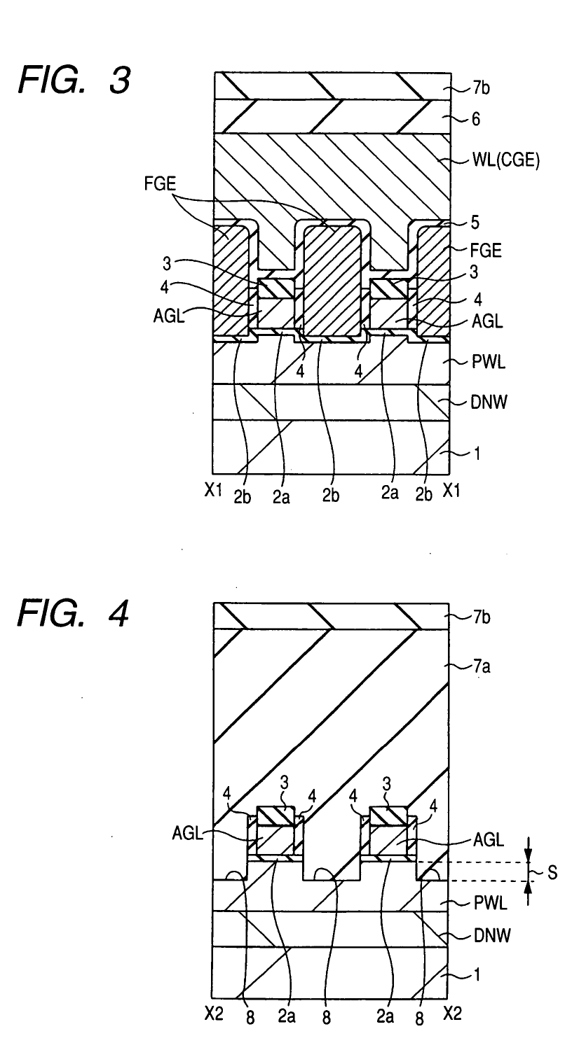

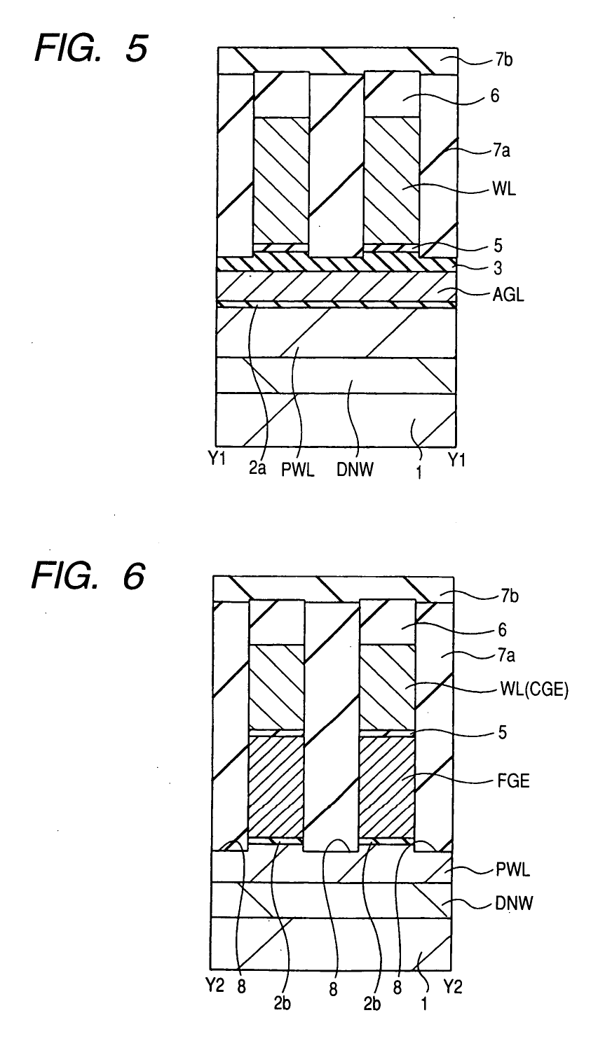

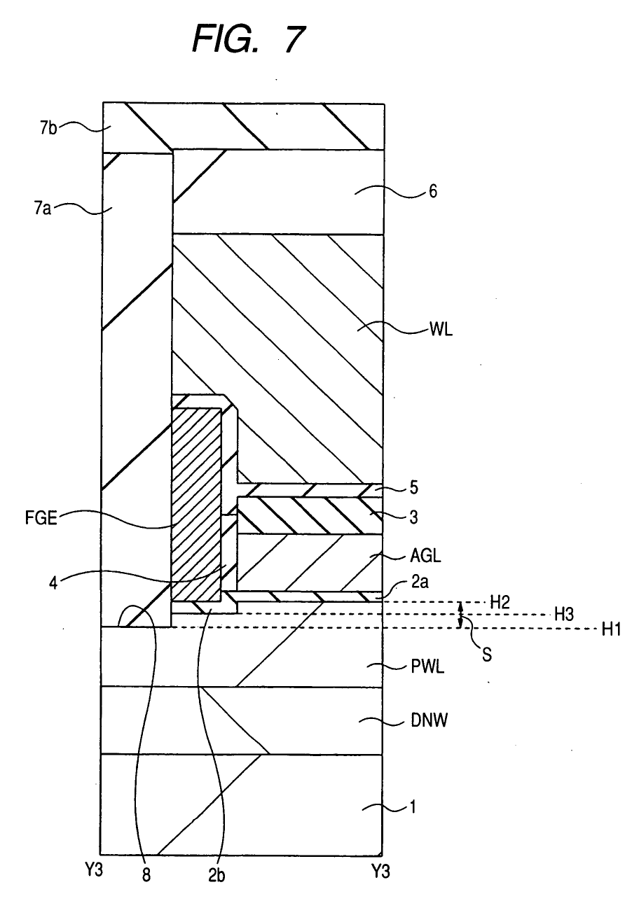

Next, FIG. 2 is a main plane diagram illustrating a memory array shown in FIG. 1 when a flash memory is not in operation, FIG. 3 a cross-sectional drawing at the position of line X1-X1 shown in FIG. 2, FIG. 4 a cross-sectional drawing at the position of line X2-X2 shown in FIG. 2, FIG. 5 a cross-sectional drawing at the position of line Y1-Y1 shown in FIG. 2, FIG. 6 a cross-sectional drawing at the position of line Y2-Y2 shown in FIG. 2, and FIG. 7 an enlarged cross-sectional drawing at the position of line Y3-Y3 shown in FIG. 2. FIG. 2 is a plane diagram, but dotted shading is applied in the junction isolation regions (active region) to make the drawing easy to view. Moreover, a part of the material is omitted to make the drawing easy to view in FIG. 2.

The memory array of a flash memory of the first embodiment is understood to consist of a so-called contact-less type array which does not have a contact hole in each memory cell MC. The substrate 1 consists of, for instance, a p-type silicon (Si) single crystal. The symbols DNW and PWL designate an n-type buried region and a p-well, respectively. The p-well PWL is surrounded by the underlayer n-type buried region DNW. A plurality of band-shaped assist gate wirings (first gate electrodes) AGL lying along the first direction Y in FIG. 2 are arranged on the main surface of the substrates (second main surface) through, for instance, the gate insulator film (first gate insulator film) 2a composed of silicon oxide (SiO₂ etc.) lying in mutual alignment along the second direction X shown in FIG. 2. Each assist gate wiring AGL consists of, for instance, low-resistance polysilicon, and cap insulator films 3 composed of, for instance, silicon oxide are formed thereon. Moreover, sidewalls (sidewall insulation films) 4 composed of, for instance, silicon oxide are formed on the sidewall of each assist gate AGL and cap insulator film 3.

An n-type semiconductor region for the drain line DL and the source line SL is not formed on the substrate 1. An n-type inversion layer is created in the main surface section of the substrate 1 which is facing the assist gate wiring AGL by applying a desired voltage to the assist gate wiring AGL in the case of the programming and reading operations of the flash memory, thereby, the aforementioned drain line DL (drain region) and source line SL (source region) are formed. That is, since the inversion layer is used for the local data line BL, a diffusion line is not necessary in the memory array, resulting in the possibility of a reduction in the data line pitch. Moreover, since a trench isolation region is not formed, it is possible to make the area of the memory array smaller. Furthermore, since the configuration is one in which the drain line DL and the source line SL of the adjacent memory cells MC are shared, it is possible to make the footprint of the memory array smaller.

A plurality of band-shaped word lines WL lying along the second direction in FIG. 2 are arranged in mutual alignment along the first direction Y in FIG. 2 through the aforementioned cap insulator film 3 and the interpoly dielectric film 5 over the assist gate wiring AGL. The insulator film 5 is formed as a stacked film in which, for instance, a silicon oxide film, a silicon nitride (Si₃N₄ etc.), and a silicon oxide film are deposited in order from the underlayer. Each word line WL is formed as a stacked film of, for instance, low-resistance polysilicon and a tungsten silicide (WSiₓ) formed thereon, and a part of the word line WL becomes the aforementioned control gate electrode CGE. An insulator film 6 composed of, for instance, silicon oxide is formed on top of each word line WL.

The aforementioned floating gate electrode FGE of the aforementioned memory MISQm is formed in a condition insulating it from the other portions at the position where it is between the adjacent assist gate wirings AGL and the planar stacked word lines WL, that is, between the opposing faces of the control gate electrode CGE and the substrate 1. The floating gate electrode FGE is composed of, for instance, low-resistance polysilicon and formed on the main surface of the substrate 1 (third main surface section) through the gate insulator film 2b composed of, for instance, a silicon oxide film. The floating gate electrode FGE is dielectrically separated from the assist gate wiring AGL by the aforementioned sidewall 4, and dielectrically separated from the word line WL by the aforementioned insulator film 5. The floating gate electrode FGE is formed with a convex-shaped cross-section such that its upper surface is higher than the upper surface of the assist gate wiring AGL. In the case when it is a configuration in which the floating gate electrode having a concave-shaped cross-section is formed between the adjacent assist gate wiring s AGL, the thickness of the conductive film to fabricate the floating gate electrode FGE has to be made thinner because the space between the adjacent assist gate wiring AGL becomes narrower when the size of memory cell MC is reduced, resulting in patterning the floating gate electrode being difficult. On the other hand, in the case when the cross-section of the floating gate electrode is made to have a convex shape, a reduction in the size of the memory cell MC can be proceed because the patterning of the floating gate electrode FGE can be made easier even if the size of the memory cell is reduced. Moreover, since the capacitor of the floating gate electrode FGE and the control gate electrode CGE is formed on the convex-shaped sidewall of the floating gate electrode FGE and the convex-shaped upper surface, the opposing area between the floating gate electrode FGE and the control gate electrode CGE can be increased by increasing the height of the floating gate electrode FGE even if the minimum patterning size is reduced further. That is, since the capacity of the capacitor can be increased without increasing the footprint of the memory cell MC, the coupling ratio of the floating gate electrode FGE and the control gate electrode CGE can be improved. Therefore, it is possible to improve the controllability of the voltage control of the floating gate electrode FGE by the control gate electrode CGE, thereby, the programming and erasing speed of the flash memory can be improved even at a low voltage, and the operation voltage of the flash memory can be made lower. That is, both a reduction in size and operation at low voltage can be achieved.

The insulator films 7a and 7b composed of, for instance, silicon oxide are deposited over the main surface of such a substrate 1, in order from the bottom. This insulator film 7a is embedded between the mutually adjacent word lines WL lying along the first direction Y and between the mutually adjacent floating gate electrodes FGE lying along the first direction Y, and this insulator film 7a provides dielectrically isolation between the mutually adjacent word lines WL lying along the first direction Y and between the mutually adjacent floating gate electrodes FGE lying along the first direction Y.

At the main surface of the substrate 1, the memory array of a flash memory described in the first embodiment has a region where the height of the first main surface section, on which the assist gate wiring AGL and the word line WL are not provided, becomes lower than that of the second main surface section on which the assist gate wiring AGL is provided. That is, on the main surface of the substrate 1, a concave portion 8 is formed in at least one part of the junction isolation region surrounded by the assist gate wirings AGL and the word lines WL. A part of the aforementioned insulator film 7a is also embedded in the aforementioned concave portion 8. In the first embodiment, the third main surface section of the substrate 1 to which the floating gate electrode FGE is facing is slightly cut away by the removal process of the etching damage layer described later. Therefore, as shown in FIG. 7, the height H3 of the aforementioned third main surface section is lower than the height H2 of the second main surface section of the substrate 1 to which the assist gate wiring AGL is facing, but it is higher than the height H1 of the bottom surface (first main surface section) of the aforementioned concave portion 8.

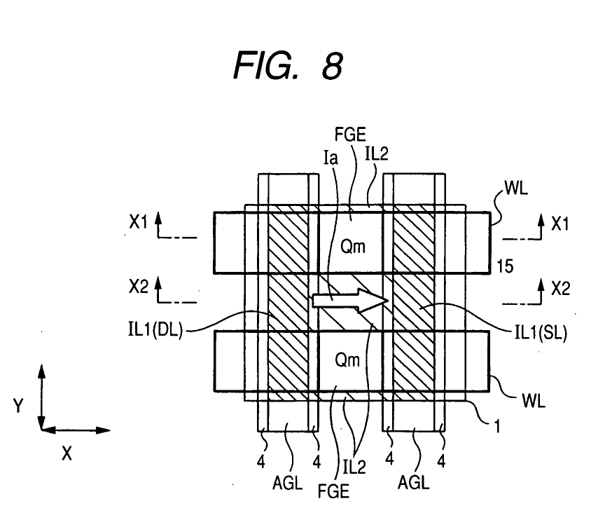

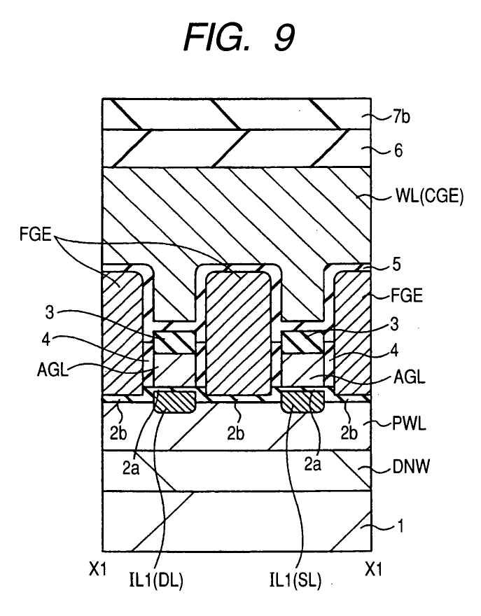

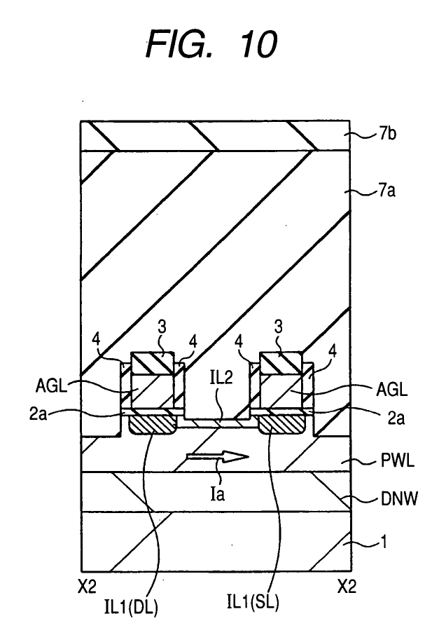

The reason to provide such a concave portion 8 is that there are the following problems. FIG. 8 is a main plane drawing of a memory array of, for instance, a 4 Gb AND type flash memory, FIG. 9 a cross-sectional drawing at the position of line X1-X1 shown in FIG. 8 in the case of programming and reading operations, and FIG. 10 a cross-sectional drawing at the position of line X2-X2 shown in FIG. 8 in the case of the programming and reading operations. In FIG. 8, dotted shading is applied in the inversion layers IL1 and IL2 to make the drawing easy to view.

In FIGS. 8 to 10, the heights of the first main surface section and the third main surface section are slightly lower than the height of the second main surface section of the substrate 1 to which the assist gate wiring AGL is facing because the first main surface section of the substrate 1 in the junction isolation region surrounded by the assist gate wiring AGL and the word line WL and the third main surface section of the substrate 1 to which the floating gate electrode FGE is facing are cut away by the removal process of the above-mentioned etching damage layer. However, there is no deep concavity like the aforementioned concave portion 8. Other than that, it is the same as the descriptions in FIGS. 2 to 7, and the inversion layer IL1 is formed on the substrate 1 by applying a desired voltage to the assist gate wiring AGL during programming and reading as described above, and it is used as the source line SL and the drain line DL. However, in order to make the resistance of the inversion layer IL1 to be the same as that of the diffusion layer, it is necessary to apply a high voltage to the assist gate wiring AGL. Because of it, the inversion layer IL1 is formed extending not only right under the assist gate wiring AGL but also outside (both sides of the second direction X2) as shown by the inversion layer IL2. Therefore, if the distance between the mutually adjacent assist gate wirings AGL is smaller, the distance between the mutually adjacent inversion layers IL1 becomes even smaller. It is hard for a nonconformity such as a flow of leakage current to occur because a desired threshold value is provided right underneath the floating gate electrode FGE, even if it is between the mutually adjacent assist gate wiring AGL. However, in the region surrounded by the assist gate wirings AGL and the word line WL and in the junction isolation region on which any gate electrode is not present, there is a problem that a leakage current Ia shown as an arrow increases rapidly and both programming and reading operations cannot be possible. Therefore, since the 90 nm generation, a reduction in bit cost has not been compatible with high-speed programming. Moreover, although the chip size can be reduced when the number of memory cells which can connect with one bit line is increased, the number of connecting memory cells is limited by the value of the leakage current between the above-mentioned source line SL and drain line DL, so that there is also a problem that an increase in the leakage current prevents an increase in the number of connecting memory cells and a reduction in the chip size. Furthermore, since the issue of an increase of the leakage current becomes serious with a reduction in the gate length of the memory cell, it also becomes an impediment to the reduction in the gate length of the memory cell, so that a problem arises that it prevents an improvement in integration (that is, an increase in the capacity of the memory chip) and a reduction in the chip size.

Then, in the first embodiment, as described in FIGS. 2 to 7, the concave portion 8 is formed at least one part of the junction isolation region surrounded by the assist gate wiring AGL and the word line WL on the main surface of the substrate 1. As a result, the leakage current flowing between the drain line DL/source line SL at the junction isolation region can be controlled, resulting in the ability to reduce the leakage current flowing between data lines. Therefore, a reduction in the bit defects of flash memory makes it possible to improve the yield of flash memory. Moreover, since the leakage current flowing between the data lines can be reduced, it is possible to increase the number of memory cells MC which can be connected with one data line. Therefore, a reduction in the size of flash memory can proceed because the area of the semiconductor chip can be reduced. Moreover, since the leakage current flowing between the drain line DL/source line SL can be reduced, the channel length underneath the floating gate electrode FGE can be reduced. Therefore, the size of the memory cell MC can be reduced, so that an increase in the capacity of the memory chip and a reduction in the size of the semiconductor chip can be promoted.

In order to reduce the leakage current flowing between the source line SL/drain line DL, the length (width) of the concave portion 8 in the first direction (columnwise direction) Y needs to be greater than at least the space between the adjacent word lines WL in the first direction Y. In the memory array of the flash memory of the first embodiment, the length of the concave portion 8 in the first direction Y is made the same as the space between the adjacent word lines WL. Moreover, the length (width) of the concave portion in the second direction (line writing direction) X is not always made greater than or equal to the space between the adjacent assist gate wirings AGL in the second direction X, and it may be less than or equal to the space between the adjacent assist gate wirings AGL. In the memory array of the flash memory of the first embodiment, the concave portion 8 is formed at the region of the substrate 1 on which the assist gate wiring AGL, the word line WL, and the sidewall 4 are not provided. That is, the width of the concave portion 8 in the second direction X is made the same as the space between the adjacent sidewalls 4 in the second direction X. As a result, the portion in which the inversion layer IL1 is formed underneath the sidewall 4 can be maintained and the cross-sectional area of the inversion layer IL1 is not cut away unnecessarily, so that the resistance of the inversion layer IL1 can be made smaller.

The step difference S underneath the assist gate wiring AGL between the first main surface section of the substrate 1 and the bottom of the concave portion (second main surface section) needs to be at least greater than or equal to the depth of the inversion layer IL1. Concretely, since the inversion layer IL1 is formed about 5 nm in depth from the height of the first main surface section H1 of the substrate underneath the assist gate wiring AGL, it is necessary for the step difference to be at least 5 nm or more. In order to ensure the reduction in the leakage current between the source line SL/drain line DL in the flash memory since the 90 nm generation, it is preferable that this step difference S is made to be 20 nm or more.

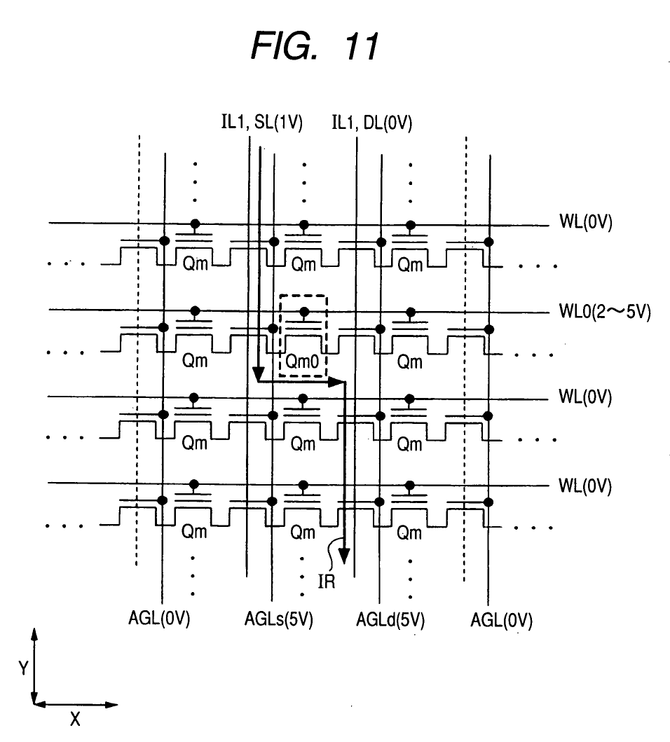

Next, the operation examples of a flash memory of the first embodiment are explained by using FIGS. 11 to 16.

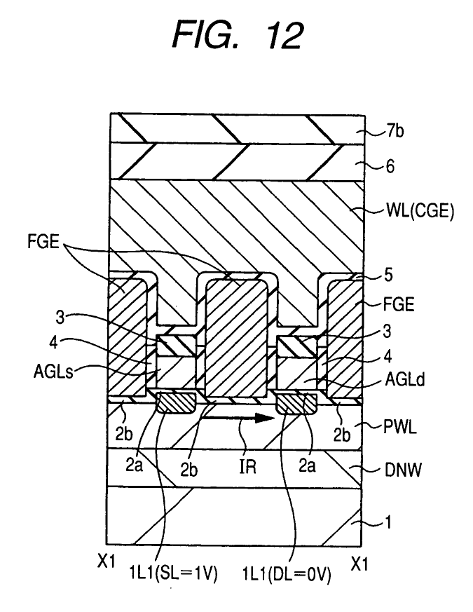

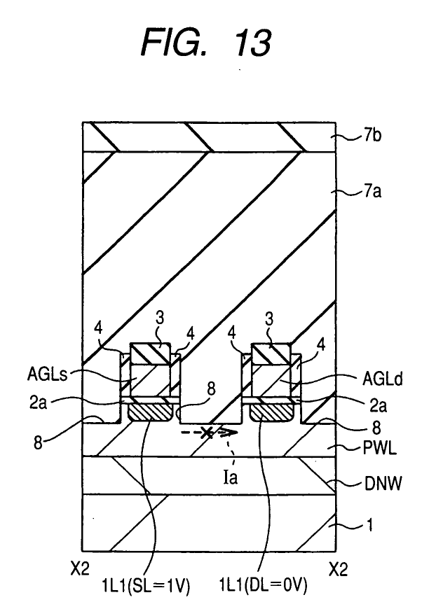

FIG. 11 is a main circuit drawing of a memory array in the case of a reading operation, FIGS. 12 and 13 cross-sections at the position of line X1-X1 and the position of line X2-X2 of FIG. 2 in the case of a reading operation, respectively.

In the case of data reading operation, the threshold value of the selected memory MIS•FETQm0 is decided by applying, for instance, about 2 to 5 V to the word line WL0 to which the control gate electrode CGE of the memory MIS•FETQm0 of the selected memory cell is connected. Moreover, a non-selected memory MIS•FETQm is made off by applying, for instance, 0 V or a negative voltage of about −2 V to the other word line. Furthermore, the n-type inversion layers IL1 for the source line SL and the drain line DL are formed on the main surface section of the substrate 1 to which the assist gate wirings AGLs and AGLd are facing, respectively, by applying, for instance, about 5 V to the assist gate wirings AGLs and AGLd to fabricate source and drain of the selected memory MIS•FETQm0. Isolation of the selected memory MIS•FETQm0 and the non-selected memory MIS•FETQm is performed by avoiding formation of an inversion layer on the main surface section of the substrate 1, to which these assist gate wirings AGL are facing, by applying for instance 0 V to the other assist gate wirings AGL. Herein, for instance, about 1 V is applied to the global data line to which is connected the n-type inversion layer IL1 for the source line SL of the selected memory MIS•FETQm0. On the other hand, for instance, 0 V is applied to the other global data line. In this condition, the applied voltage of about 0 V to the common drain line is supplied to the drain of the selected memory MIS•FETQm0 through the n-type inversion line IL1 for the drain line DL. As a result, reading data of the selected memory MIS•FETQm0 is performed by flowing a reading current IR from the global data line to the common drain line. At this time, the threshold voltage of the selected memory MIS•FETQm0 is changed under the condition of an accumulating charge of the floating gate electrode FGE. Thus it is possible for the data of the selected memory MIS•FETQm0 to be decided by the condition of the current flowing between the source and drain of the selected memory MIS•FETQm0. Moreover, as shown in FIG. 13 of the first embodiment, flowing of a leakage current Ia between the source line SL/drain line DL can be controlled and prevented at the junction isolation region while reading data by providing the concave portion 8 at the aforementioned junction isolation region.

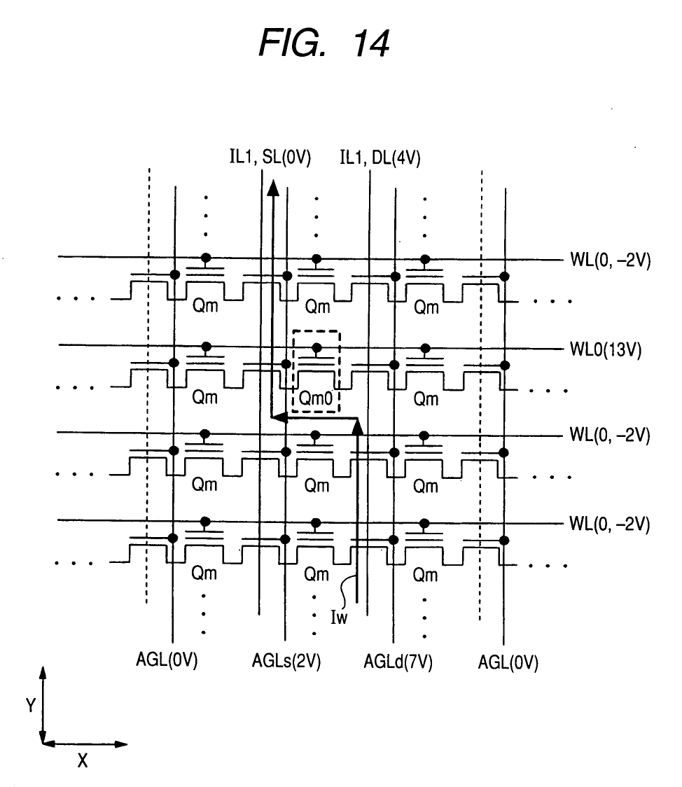

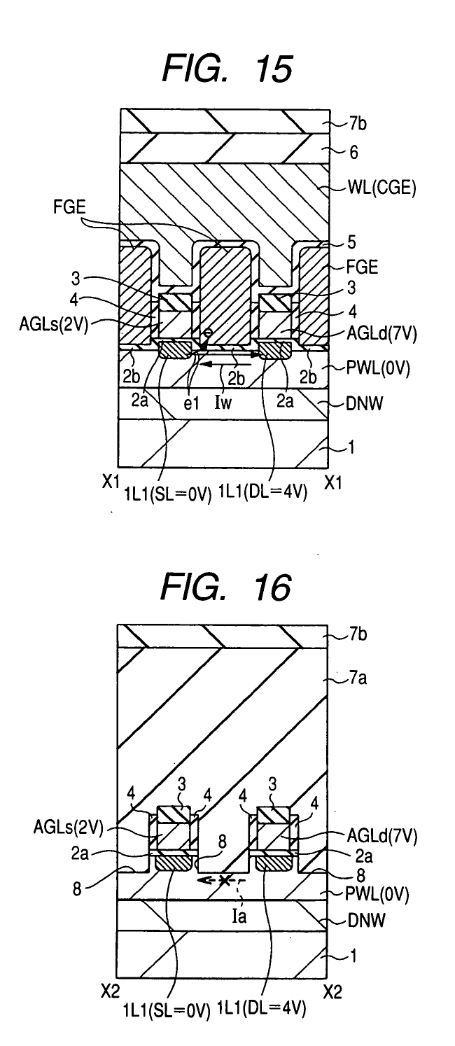

Next, FIG. 14 is a main circuit drawing of a memory array in the case of a programming operation, FIGS. 15 and 16 cross-sectional drawings at the position of line X1-X1 and the position of line X2-X2 in FIG. 2, respectively, in the case of a programming operation.

Programming is predicated on a source side hot electron injection technique by a source side selection and constant charge injection. Because of this, efficient programming becomes possible using a low current. In the programming operation, for instance, about 13 V to 15 V and 0 V are applied to the word line WL0 to which the control gate electrode CGE of the memory MIS•FETQm0 of the selected memory cell MC is connected and the other word lines WL, etc. are applied, respectively. An n-type inversion layer IL1 to fabricate the source is formed at the main surface section of the substrate 1, to which the assist gate wiring AGLs is facing, and an n-type inversion layer IL1 to fabricate the drain is formed at the main surface of the substrate 1, to which the assist gate wiring AGLd is facing, by applying, for instance, about 1 V to the assist gate wiring AGLs to fabricate the source of the selected memory MIS•FETQm0, and for instance, about 7 V to the assist gate wiring AGLd for forming the drain of the selected memory MIS•FETQm0. Isolation of the selected memory MIS•FETQm0 and the non-selected memory MIS•FETQm is performed by avoiding formation of the inversion layer at the main surface section of the substrate 1, to which these assist gate wirings AGL are facing, by applying for instance, 0 V to the other assist gate wirings AGL. In this condition, the applied voltage of about 4 V to the common drain line CD is supplied to the drain of the selected memory MIS•FETQm0 through the n-type inversion line IL1 for the drain line DL. Herein, for instance, 0 V is applied to the global data line to which the n-type inversion layer IL1 for the source line SL of the selected memory MIS•FETQm0 is connected. Moreover, a p-well PWL is maintained at, for instance, 0 V. According to this, a programming current Iw flows in the selected memory MIS•FETQm0 from the drain to the source and, at this time, charges stored in the n-type inversion layer IL1 on the source side are efficiently injected as a certain amount of channel current to the floating gate electrode FGE through the insulator layer 2b (constant charge injection method), thereby, data are programmed in the selected memory MIS•FETQm0 at high speed. On the other hand, flowing drain current from the drain of the aforementioned non-selected memory MIS•FETQm0 to the source should stop to avoid data being programmed. The arrow e1 in FIG. 15 shows the schematic drawing of charge injection for data. Moreover, multivalued data can be stored in each memory cell MC (memory MIS•FETQm). This multivalued storage is performed by, for instance, maintaining the programming voltage of the word line WL constant and by changing the programming time to change the amount of hot-electrons injected into the floating gate electrode FGE, so that it is possible to form a memory cell MC having several kinds of threshold value levels. That is, four or more values such as “00”/“01”/“10”/“11” can be stored. As a result, one memory cell MC can realize the job of two memory calls MC, so that a reduction in the size of flash memory can be achieved. Moreover, in the first embodiment, as shown in FIG. 16, a flow of leakage current between the source line SL/drain line DL at the junction isolation region in the case of data programming can be controlled or prevented by providing the concave portion 8 at the junction isolation region.

Next, in the data erase operation, F-N (Fowlor Nordheim) tunnel-emission from the floating gate electrode FGE to the substrate 1 is carried out by applying a negative voltage to the selected word line WL. Specifically, for instance, about −16 V is applied to the selected word line WL and a positive voltage is applied to the substrate 1. For instance, 0 V is applied to the assist gate wiring AGL and the n-type inversion layer IL1 does not form. As a result, charges for data stored in the floating gate electrode are ejected to the substrate 1 through the insulator film 2b to carry out bulk erasing of data in a plurality of memory cells MC.

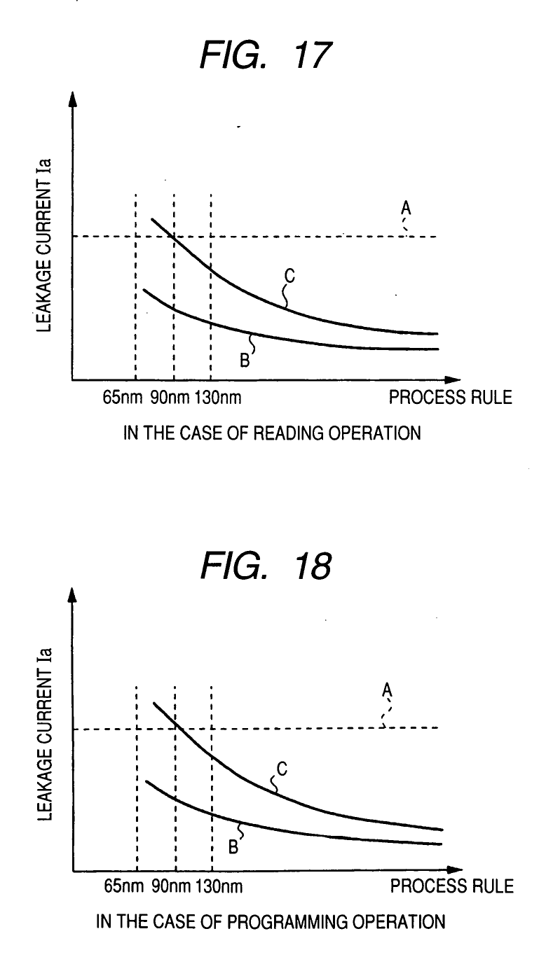

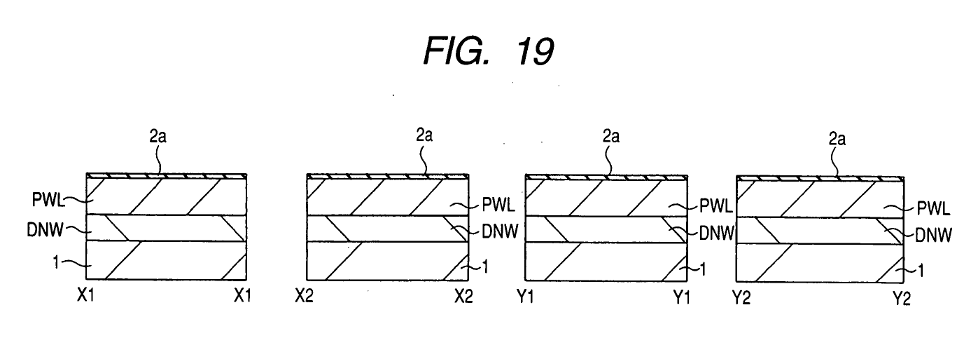

Next, FIGS. 17 and 18 show the behavior of leakage current at the junction isolation region in the cases of a data reading operation and a data programming operation by comparing the configurations shown in FIGS. 8 to 10 with those shown in the first embodiment. FIG. 17 shows the case of a data reading operation and FIG. 19 shows the case of a data programming operation. The vertical lines of FIGS. 17 and 18 show the values of leakage current Ia flowing between the source/drain and the horizontal lines show the process rule. The broken lines A in FIGS. 17 and 18 show the tolerance of the leakage current Ia, the solid line B the leakage current flowing between the source/drain at the junction isolation region of the first embodiment, and the solid line C the leakage current flowing between the source/drain at the junction isolation region of the configuration shown in FIGS. 8 to 10. Especially, it is understood that the effect of the first embodiment is remarkable when the data line pitch is small.

Next, FIGS. 19 to 32 are examples of a manufacturing method of a flash memory of the first embodiment. The positions of X1-X1, X2-X2, Y1-Y1, and Y2-Y2 in FIGS. 19 to 32 show the cross-sectional drawing at the positions of line X1-X1, line X2-X2, line Y1-Y1, and line Y2-Y2 in each manufacturing process.

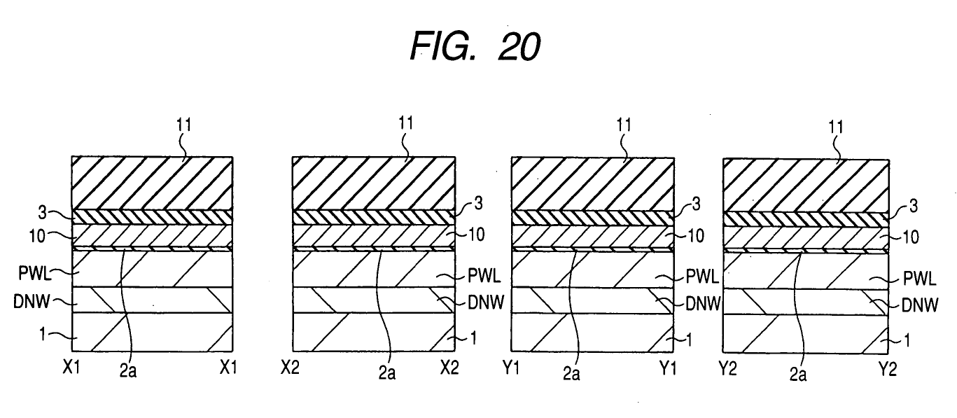

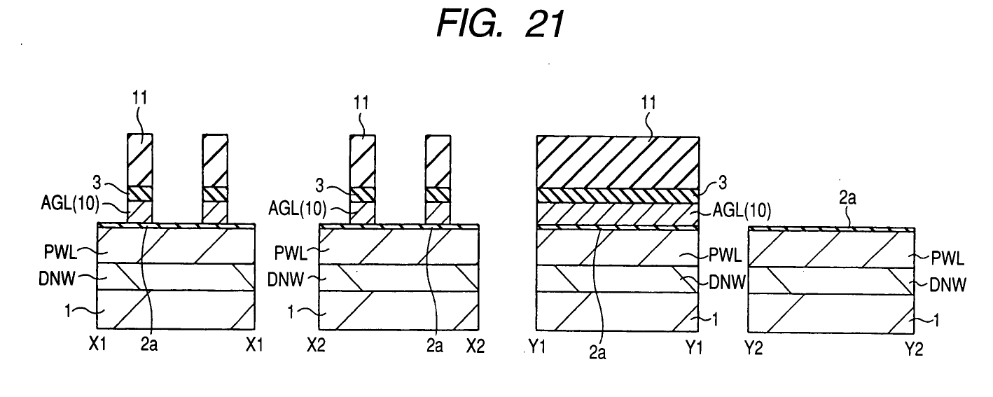

First, as shown in FIG. 19, a substrate 1 (in this step, a flat almost circular semiconductor plate, a so-called semiconductor wafer) composed of p-type silicon (Si) single crystal is prepared and an n-type buried region DNW and a p-well PWL are formed, in order, on this substrate 1. Then, a gate insulator film 2a with a thickness of about 10 nm composed of, for instance, silicon oxide, etc. is formed on the p-well PWL of the substrate 1 by a thermal oxidization technique such as ISSG (In-Situ Steam Generation). Next, as shown in FIG. 20, a conductive film 10 composed of, for instance, phosphorus (P)-doped low-resistance polysilicon is deposited on the main surface of the substrate 1, and a cap insulator film 3 composed of, for instance, silicon nitride is deposited thereon. Further on the top of it, a dummy insulator film 11 composed of, for instance, silicon oxide is deposited. The conductive film 10, the cap insulator film 3, and the dummy insulator film 11 are deposited by, for instance, a CVD (Chemical Vapor Deposition) technique. Then, as shown in FIG. 21, the assist gate wiring AGL consisting of the conductive film 10 is formed by patterning the dummy insulator film 11, the cap insulator film 3, and the conductive film 10 by applying a dry etching treatment using an etching mask. In this step, the dummy insulator film 11, the cap insulator film 3, and the assist gate wiring AGL are fabricated in a band-shaped pattern lying along the aforementioned first direction Y and arranged in a stripe shape.

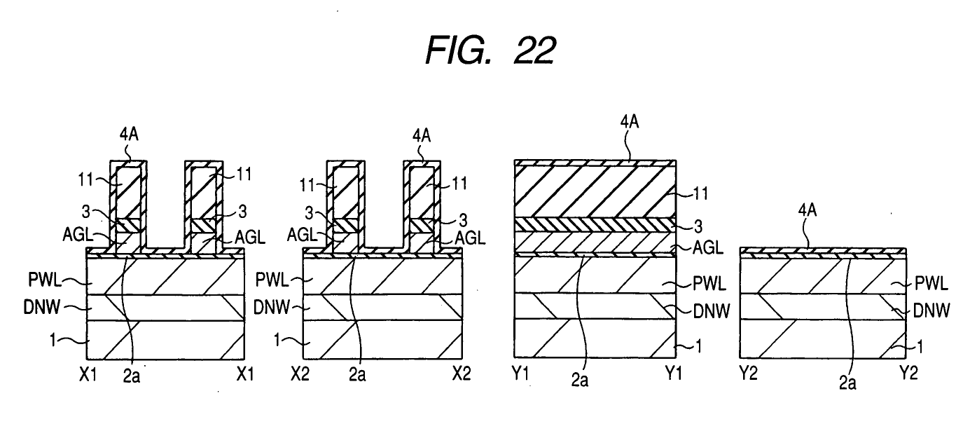

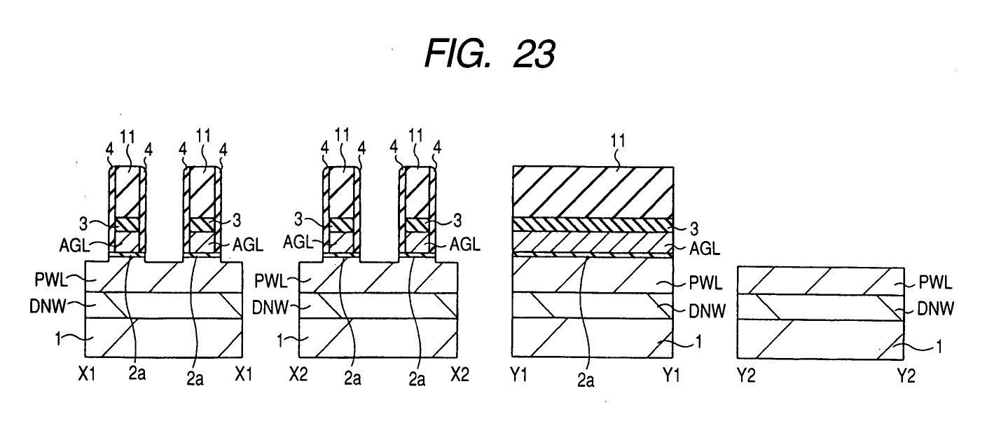

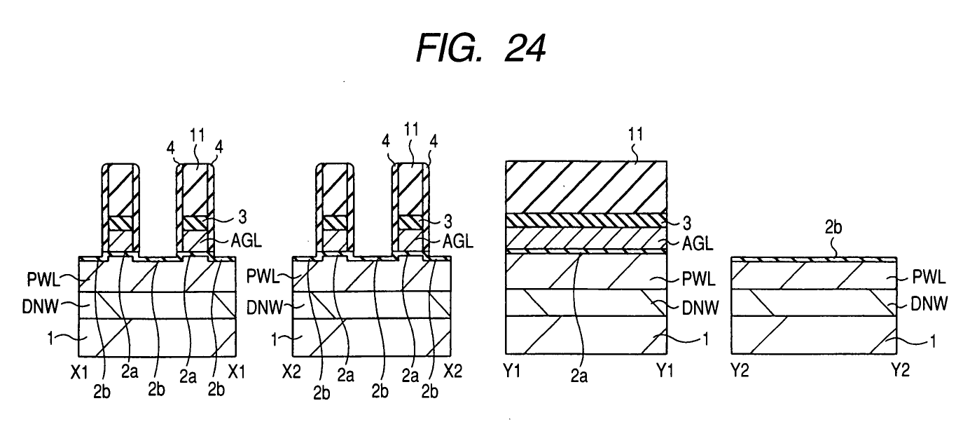

Next, as shown in FIG. 22, a thermal oxidation technique such as ISSG oxidation technique etc. is applied to the substrate 1 (semiconductor wafer) to form a high quality insulator film composed of, for instance, silicon oxide on the sidewall of the assist gate wiring AGL, etc. Then, an insulator film 4A composed of, for instance, silicon oxide is deposited on the main surface of the substrate 1 by a CVD technique using, for instance, TEOS gas. The insulator film 4A is deposited so as not to completely imbed the space between the stripe-shaped pattern consisting of the aforementioned dummy insulator film 11, the cap insulator film 3, and the assist gate wiring AGL. Then, as shown in FIG. 23, the sidewall 4 is formed on the sidewall of the stacked pattern consisting of the assist gate wiring AGL, the cap insulator film 3, and the dummy insulator film 11 by performing etchback of the insulator film 4A. Moreover, at this time, the gate insulator film 2a is also removed, which is located at the bottom of the space between adjacent stripe-shaped patterns consisting of the aforementioned dummy insulator film 11, the cap insulator film 3, and the assist gate wiring AGL. According to this step, the gate insulator film 2a is left only underneath the assist gate wiring AGL and the sidewall 4. Since this etching process is performed under a condition for etching silicon oxide film, an etching damage layer is formed on the main surface of the substrate 1 at the space section between the stripe-shaped patterns formed along the aforementioned first direction Y (referring to FIG. 2). In order to remove this etching damage layer, a further etching process is performed under a condition for etching silicon (etching damage removal process). According to this process, the space section of the main surface of the substrate 1, which is located between the stripe-shaped patterns formed along the aforementioned first direction Y, becomes about 10 nm lower than the main surface of the substrate 1 underneath the assist gate wiring AGL. Removal of the etching damage layer may be done in a manner such that the thermal oxide film is removed by a wet etching after the thermal oxidization of the main surface of the substrate 1. Then, as shown in FIG. 24, after an insulator film composed of, for instance, silicon oxide is formed on the main surface of the substrate 1 by applying a thermal oxidation treatment, such as an ISSG oxidation technique, to the main surface of the substrate 1, a heat treatment is applied in a gas atmosphere containing nitrogen (N) (oxynitriding treatment) to form the gate insulator film 2b composed of silicon oxynitride (SiON) by the segregation of nitrogen at the interface of the insulator film and the substrate 1. This gate insulator film 2b is a film functioning as a tunnel insulator film of the memory MIS•FETQm, and the thickness is, for instance, about 9 nm, equivalent to the film thickness of silicon dioxide. The gate insulator film 2b may be formed by a CVD technique.

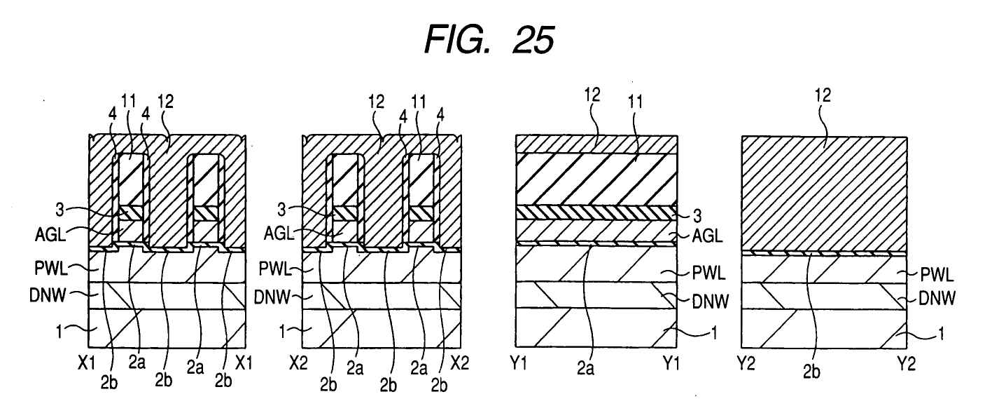

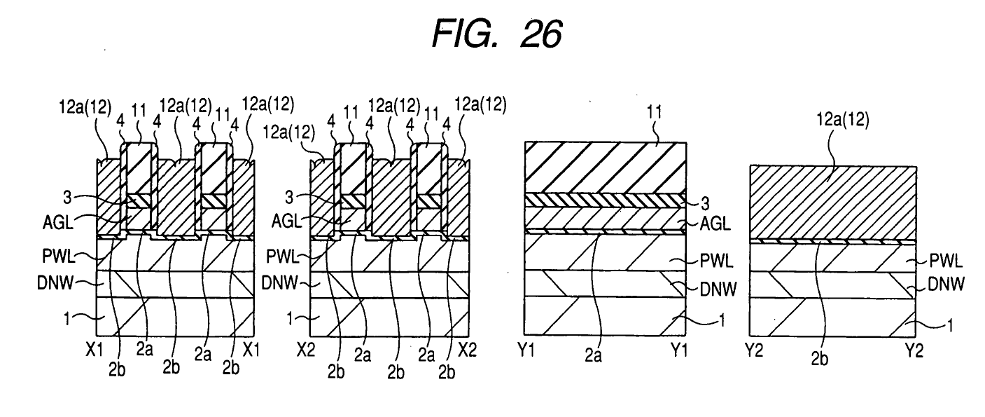

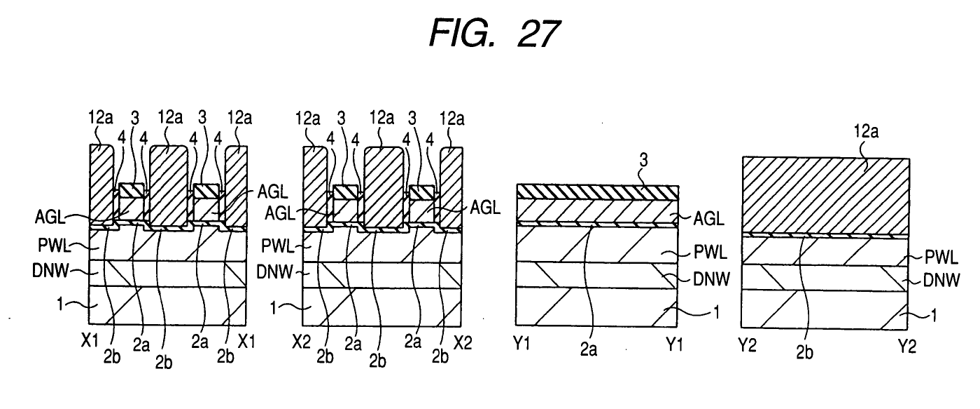

Then, as shown in FIG. 25, the conductive film 12 to fabricate the floating gate electrode composed of, for instance, low-resistance polysilicon is deposited on the main surface of the substrate 1 (semiconductor wafer) by a CVD technique to completely fill the space between the adjacent stripe-shaped patterns consisting of the aforementioned dummy insulator film 11, the cap insulator film 3, and the assist gate wiring AGL. As shown in FIG. 26, the conductor pattern 12a for forming the floating gate electrode is formed at the space between the stripe-shaped patterns consisting of the aforementioned dummy insulator film 11, the cap insulator film 3, and the assist gate wiring AGL by applying an etchback treatment using an anisotropic dry etching technique or a chemical mechanical polishing (CMP) treatment to the conductive film 12 on the main surface of the substrate 1. Next, as shown in FIG. 27, the dummy insulator film 11 and the sidewall 4 are etched by using a dry etching technique or a wet etching technique. At this time, the etching selection ratio of silicon oxide, silicon, and silicon nitride should be large in order to make the silicon oxide easier to remove than silicon and silicon nitride. As a result, the cap insulator film 3 composed of silicon nitride is made to function as an etching stopper. Moreover, the dummy insulator film 11 composed of silicon oxide is totally removed, but the sidewall 4 composed of silicon oxide is removed only at the upper part and the rest of it is left on the sidewall of the assist gate wiring AGL.

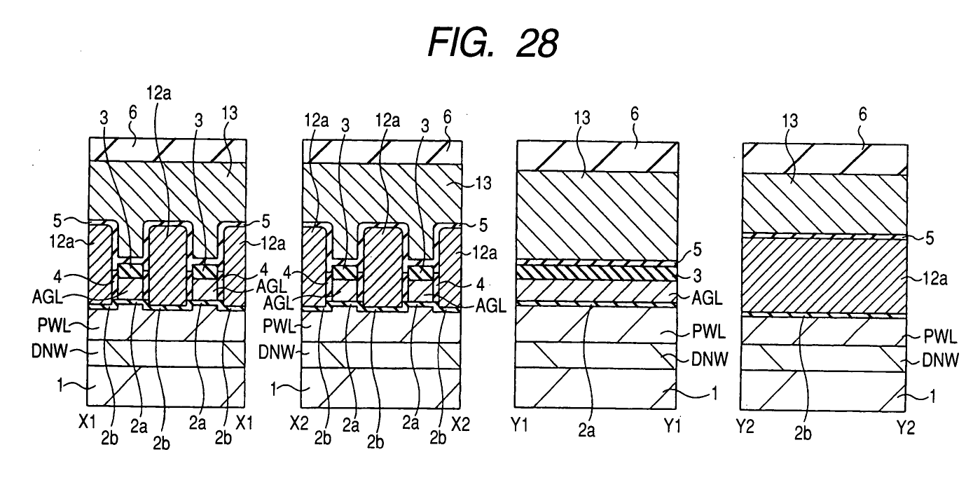

Next, as shown in FIG. 28, the interpoly dielectric film 5 is formed, which provides electrical insulation between the floating gate electrode and the control gate electrode. For instance, a silicon oxide film or a stacked film consisting of silicon oxide film/silicon nitride film/silicon oxide film can be used for the interpoly dielectric film 5. Then, the conductive film 13 to fabricate the word line is deposited on the insulator film 5. The conductor film 13 is formed by depositing, for instance, a low-resistance polysilicon film and a tungsten silicide film from the underlayer, in order. Then, the insulator film 6 composed of, for instance, silicon oxide is deposited on the conductive film 13 by a CVD technique, etc.

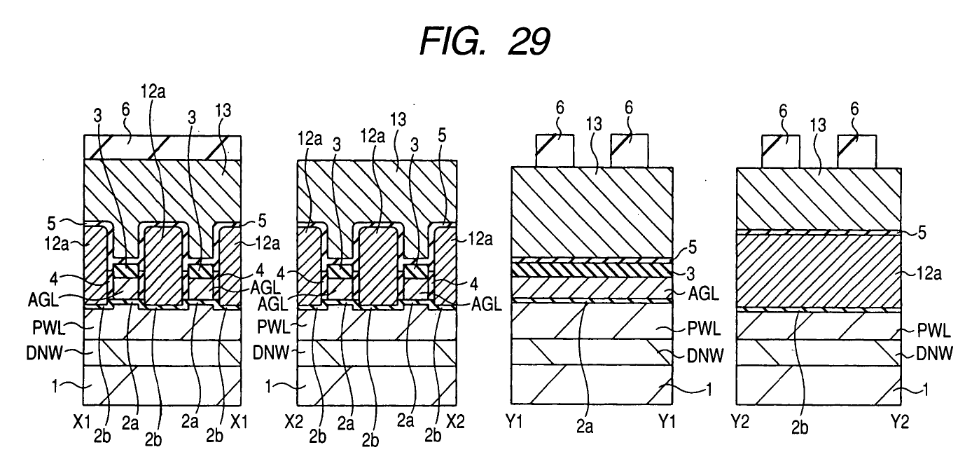

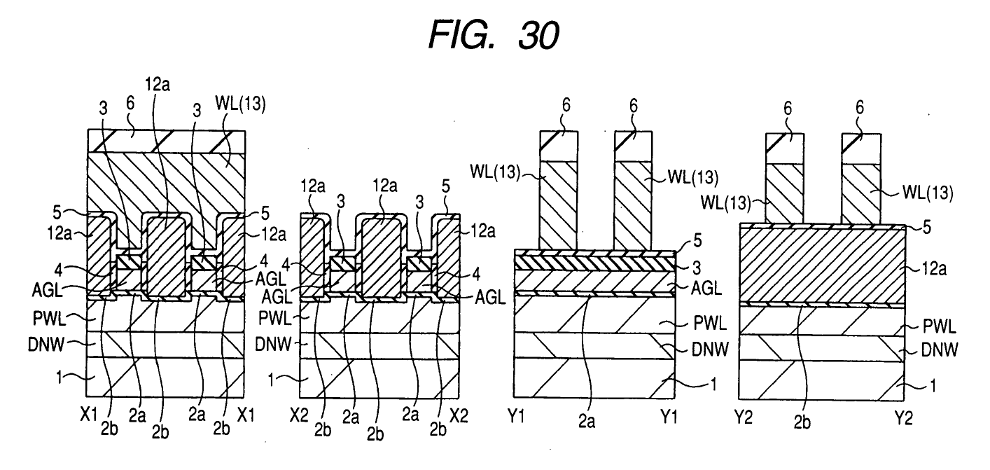

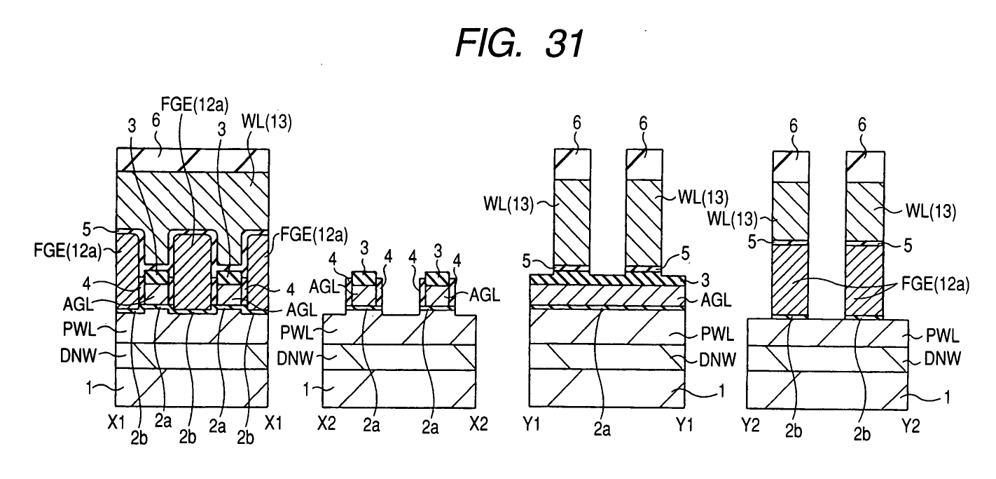

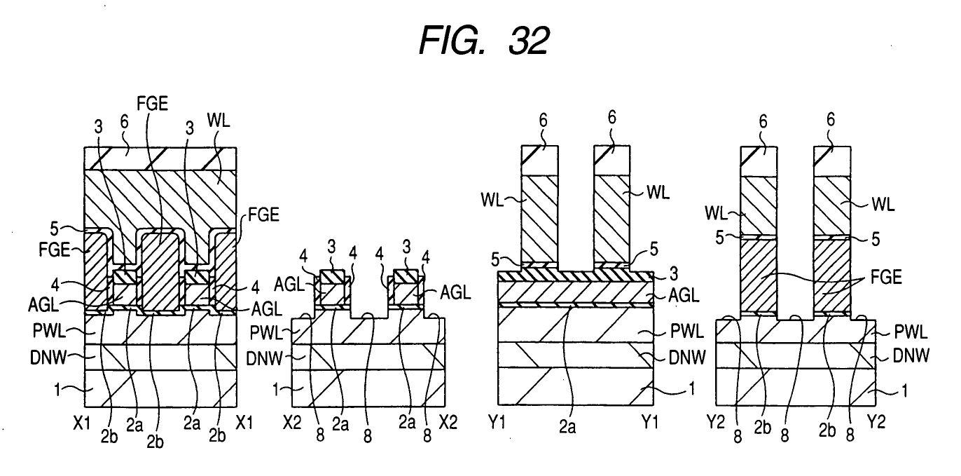

Next, as shown in FIG. 29, after pattering the insulator film 6 by a dry etching treatment using the resist pattern as an etching mask, the conductor film 13 exposed from the pattern of the insulator film 6 is removed by a dry etching technique using this as an etching mask, resulting in the word line WL consisting of the conductor film 13 being formed as shown in FIG. 30. Next, as shown in FIG. 31, using the pattern of the insulator film 6 as an etching mask, the floating gate FGE consisting of the conductive pattern 12a is formed by removing the insulator film 5 and the conductive pattern 12a to fabricate the floating gate electrode exposed from the etching mask. Then, using the pattern of the insulator film 6, the word line WL, the cap insulator film 3, the assist gate wiring AGL, and the sidewall 4 as an etching mask, the section of the substrate 1 surrounded by the exposed aforementioned junction isolation region (the region surrounded by the assist gate wiring AGL and the word line WL) is etched deeper, resulting in the concave portion 8 being formed as shown in FIG. 32, in which the first main surface section of the substrate 1 at the aforementioned junction isolation region is made to be lower than the second main surface section of the substrate 1 underneath the assist gate wiring AGL. Since the main surface of the substrate 1 at the space between the adjacent assist gate wirings AGL is about 10 nm lower than the first main surface section of the substrate 1 underneath the assist gate wiring AGL by the removal process of the etching damage layer as mentioned above, the bottom of the concave portion 8 is made 20 nm or more lower than the main surface of the substrate 1 underneath the assist gate wiring AGL by etching the main surface of the substrate 1, 10 nm or more in this etching process.

The aforementioned concave portion 8 can be formed self-aligned against the word line WL and the assist gate wiring AGL. If the assist gate wiring AGL, the word line WL, and the floating gate electrode FGE are formed after forming the trench isolation section at the junction isolation region of the substrate 1, problems such as a reduction in yield arises caused by an increase in the area of the memory array and the characteristic related issues because of the difficulty of material matching. On the other hand, in the first embodiment, the concave portion 8 is formed self-aligned against the word line WL and the assist gate wiring AGL, so that the area of the memory array never increases even if the concave portion 8 is formed and the defect can be reduced, because the concave portion 8 can be formed with excellent alignment, resulting in flash memory with high reliability being fabricated with a high yield.

Moreover, the surface morphology of the concave portion 8 of the substrate 1 can be improved by oxidizing the surface of the substrate 1 using a thermal oxidation technique etc. after forming the concave portion 8, so that the reduction effect of the aforementioned leakage current can be enhanced. Additionally, after forming the concave portion 8, impurities such as boron (B) etc. to be an acceptor or oxygen may be injected to the junction isolation region of the substrate 1 by an ion injection technique. In the case when impurities to be an acceptor are ion-injected, the impurity concentration of the substrate 1 becomes higher, so that the reduction effect of the aforementioned leakage current can be increased. On the other hand, in the case when oxygen is ion-injected, the surface of the substrate 1 is oxidized and the surface morphology of the concave portion 8 of the substrate 1 is improved, so that the reduction effect of the aforementioned leakage current can be increased. Moreover, after forming the concave portion 8 by a dry etching technique, the corners of the bottom part of the concave portion 8 may be rounded by applying slightly a wet etching treatment. As a result, since stress concentration and field concentration can be reduced, the reliability of the flash memory can be improved.

Next, the aforementioned insulator films 7a and 7b are deposited on the main surface of the substrate 1 (semiconductor wafer), in order from the underlayer by a CVD technique to fill the concave portion 8, the space between the adjacent word lines WL and the space between the adjacent assist gate wirings AGL. Afterwards, the upper surface of the insulator film 7b is planarized by, for instance, a CMP (Chemical Mechanical Polishing) technique and, although it is not shown in the figure, the contact holes to reach the word line WL, the p-well PWL, the assist gate wiring AGL and the contact holes for power supply to the inversion layer which will be the source line/drain line located outside of the memory array are formed. Then, a metallic film is deposited and patterned to be a circuit to fabricate a flash memory shown in FIGS. 2 to 7 having a memory cell MC.

The memory cell MC of the flash memory fabricated by the above-mentioned processes can reduce the leakage current Ia in both cases of data reading and programming, which flows at the aforementioned junction isolation region while data reading and programming operations, and it makes it possible to apply a memory cell using the inversion layer IL1 underneath the assist gate wiring AGL as the source line SL/drain line DL since the 90 nm generation.

### Second Embodiment

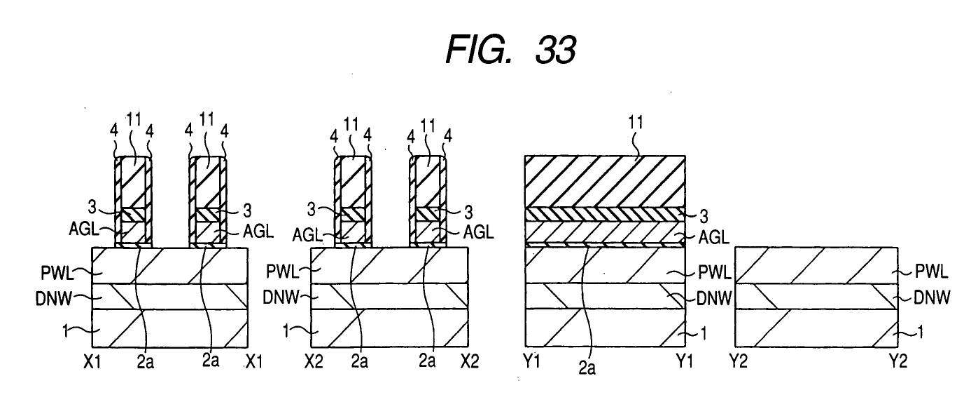

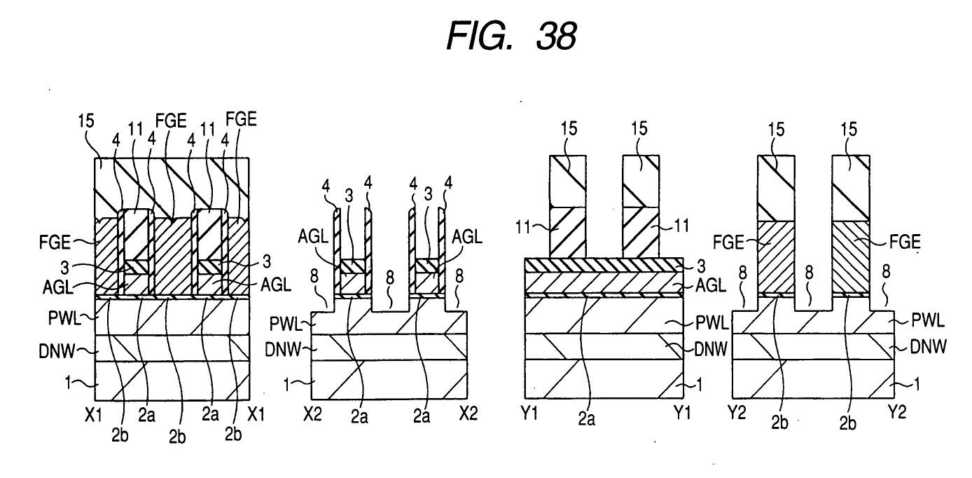

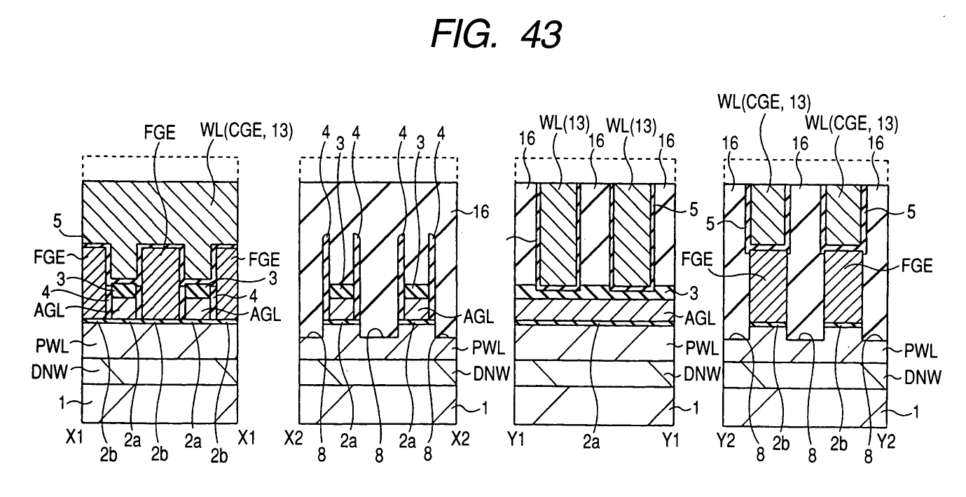

The aforementioned first embodiment described a patterning method in which the material for the control gate electrode, the insulator film for the interpoly dielectric film, and the material for the floating gate electrode are processed in one step when the floating gate electrode is separated in each memory cell. On the other hand, in the second embodiment, an example of the manufacturing method will be described referring to FIGS. 33 to 43, in which the floating gate electrode is separated in each memory cell without using the one-step process. The positions of X1-X1, X2-X2, Y1-Y1, and Y2-Y2 in FIGS. 33 to 35 and FIGS. 37 to 43 show the cross-sectional drawings corresponding to the positions of line X1-X1, line X2-X2, line Y1-Y1, and line Y2-Y2 in each manufacturing process.

First, after applying the same manufacturing process as the aforementioned first embodiment described using FIGS. 19 to 22, etch back of the insulator film 4A is performed the as same as the first embodiment to form the sidewall 4 on the sidewall of the stacked layer pattern consisting of the assist gate wiring AGL, the cap insulator film 3, and the dummy insulator film 11. Moreover, at this time, the gate insulator film 2a located at the bottom of the space between the adjacent stripe-shaped patterns consisting of the aforementioned dummy insulator film 11, the cap insulator film 3 and the assist gate wiring AGL, is also removed. In the aforementioned first embodiment, a process for removing of the etching damage layer of the substrate 1 was carried out after this process. However, in the second embodiment, an example omitting this process will be described. In the second embodiment, the cap insulator film 3 is composed of, for instance, silicon oxide, and the dummy insulator film 11 is composed of, for instance, silicon nitride.

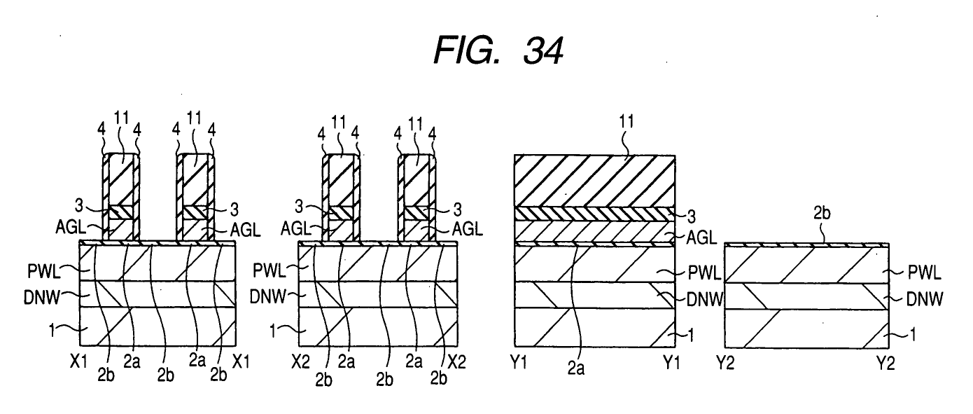

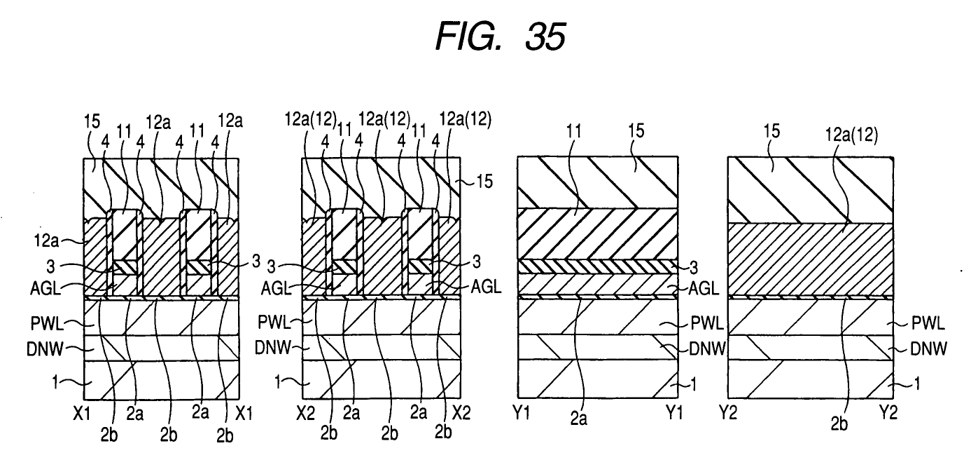

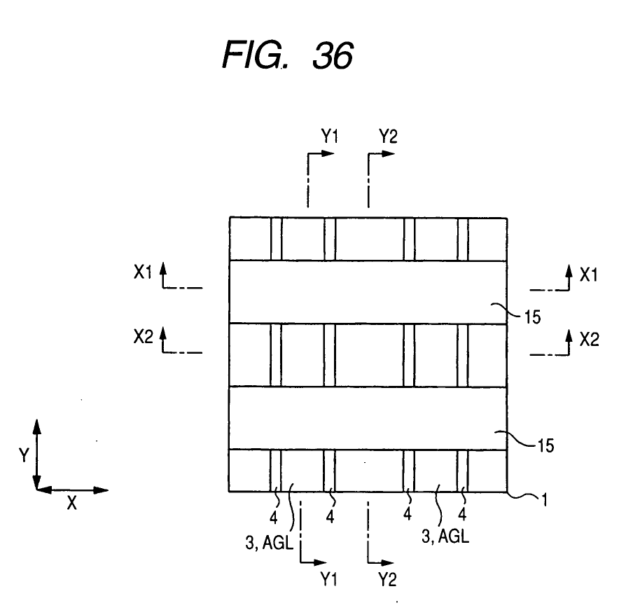

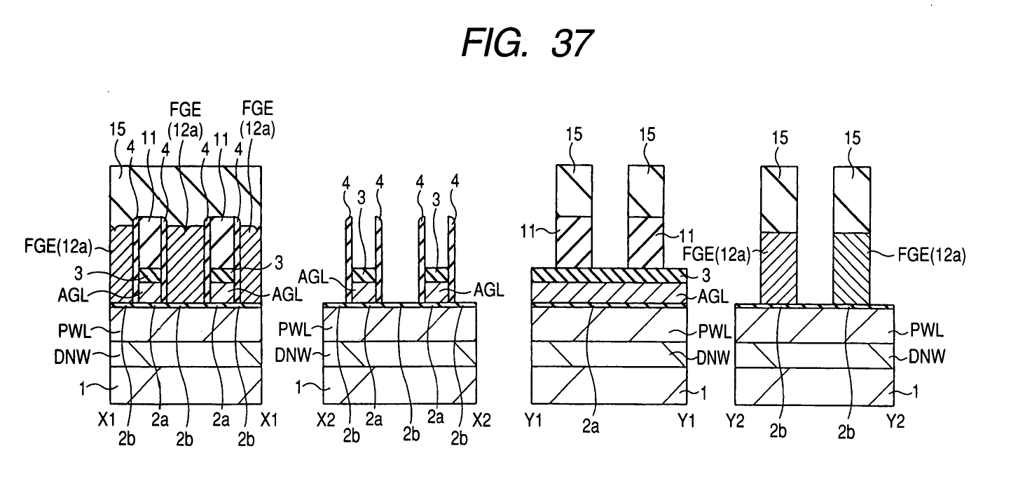

Next, as shown in FIG. 34, the gate insulator film 2b is formed on the main surface of the substrate 1 located at the space between the adjacent stripe-shaped patterns consisting of the aforementioned dummy insulator film 11, the cap insulator film 3 and the assist gate wiring AGL as described in the aforementioned first embodiment. Then, as shown in FIG. 35, the conductive film 12 is deposited to fabricate the floating gate electrode on the main surface of the substrate (semiconductor wafer) the same as the aforementioned first embodiment described using FIGS. 25 and 26, and the conductive pattern 12a to fabricate the floating gate electrode is formed at the space between the adjacent stripe-shaped patterns consisting of the aforementioned dummy insulator film 11, the cap insulator film 3 and the assist gate wiring AGL by applying an etch back treatment using an anisotropic dry etching technique or a CMP treatment. Next, after depositing the insulator film 15 composed of, for instance, silicon nitride on the upper main surface of the substrate 1 using a CVD technique, the insulator film 15, the dummy insulator film 11, and the conductive pattern 12a are etched, in order, using a stripe-shaped mask pattern lying along the second direction X shown in FIG. 2, as shown in FIGS. 36 and 37. FIG. 36 is a main plane drawing illustrating the same position of FIG. 2 at this step, and FIG. 37 shows the cross-sectional drawings at the positions of line X1-X1, line X2-X2, line Y1-Y1, and line Y2-Y2. The positions of line X1-X1, line X2-X2, line Y1-Y1, and line Y2-Y2 in FIG. 36 show the cross-sectional drawings corresponding to the same positions of line X1-X1, line X2-X2, line Y1-Y1, and line Y2-Y2 shown in FIG. 2, respectively. The assist gate wiring AGL is not cut but left lying as is along the first direction Y in FIG. 36. Moreover, the conductive pattern 12a is separated in each memory cell at this stage to become the floating gate electrodes FGE. The region in which the insulator film 15 and the dummy insulator film 11 are formed corresponds to the region in which the word line (control gate electrode) is formed in the following step.

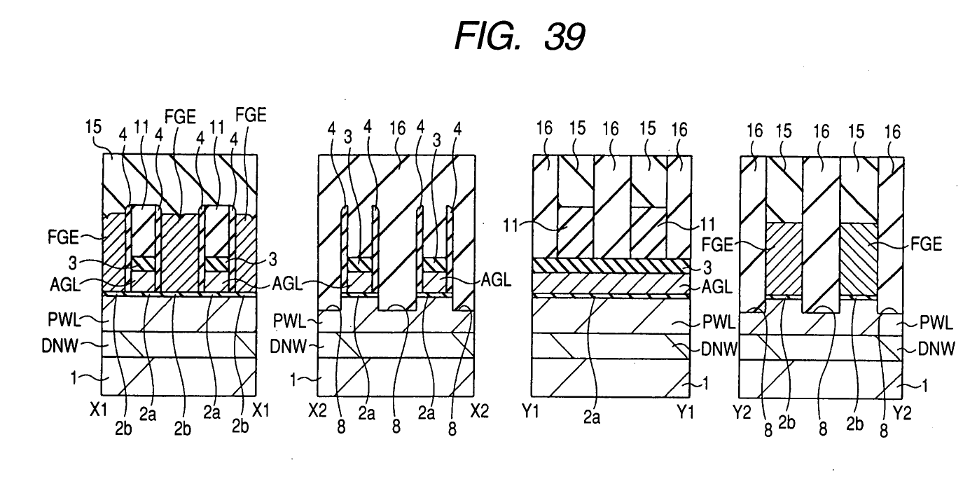

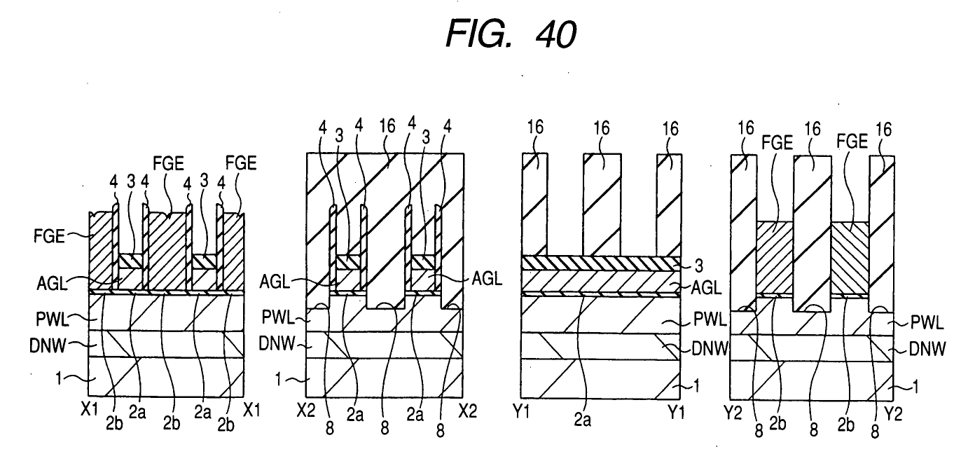

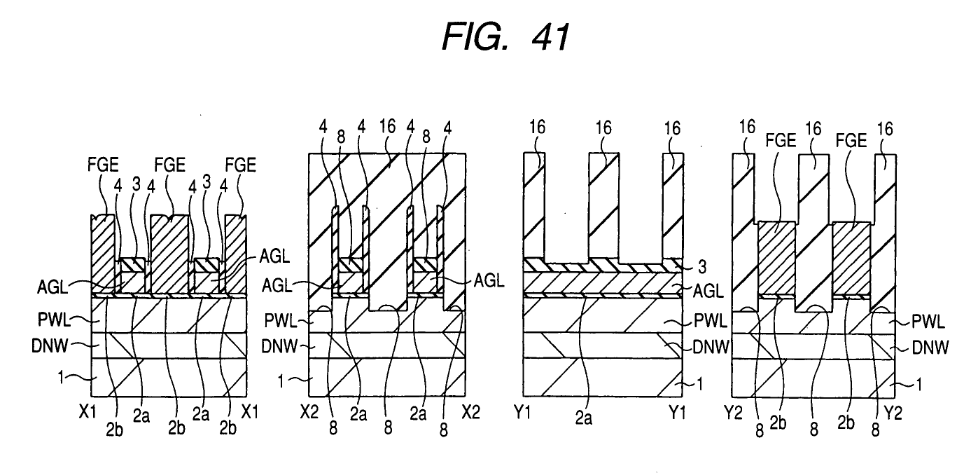

Then, the gate insulator film 2b and the substrate 1 are etched, in order, using the insulator film 15, the cap insulator film 3, and the sidewall 4 as an etching mask, resulting in the concave portion 8, in which the bottom is lower than the first main surface section of the substrate 1 underneath the assist gate wiring AGL, being formed the same as the first embodiment at the region of the substrate 1 surrounded by the assist gate wiring AGL and the word line to be formed later. Forming the concave portion 8 does not introduce an extensive increase in the manufacturing process because it is not necessary to form a particular resist pattern. As shown in FIG. 39, an insulator film 16 composed of, for instance, silicon oxide is deposited on the main surface of the substrate 1 (semiconductor wafer) by a CVD technique to completely fill the aforementioned concave portion 8, the space between the adjacent stacked film consisting of the dummy insulator film 11 and the insulator film 15, and the space between the adjacent assist gate wiring AGL, and then the upper part of the insulator film 16 is removed by an etchback technique using an anisotropic dry etching or a CMP technique until the upper part of the insulator film 15 is almost exposed. Afterwards, as shown in FIG. 40, the insulator film 15 and the dummy insulator film 11 are selectively removed by dry etching using the insulator film 16 composed of silicon oxide as an etching mask. Then, as shown in FIG. 41, the exposed part of the sidewall 4 composed of silicon oxide is removed by an isotropic etching such as wet etching etc. to expose a part and the upper surface of the floating gate electrode FGE. The sidewall 4 is left on the sidewall of the assist gate wiring AGL. Moreover, the cap insulator film 3 and insulator film 16 composed of silicon oxide are also slightly cut away in the isotopic etching process.

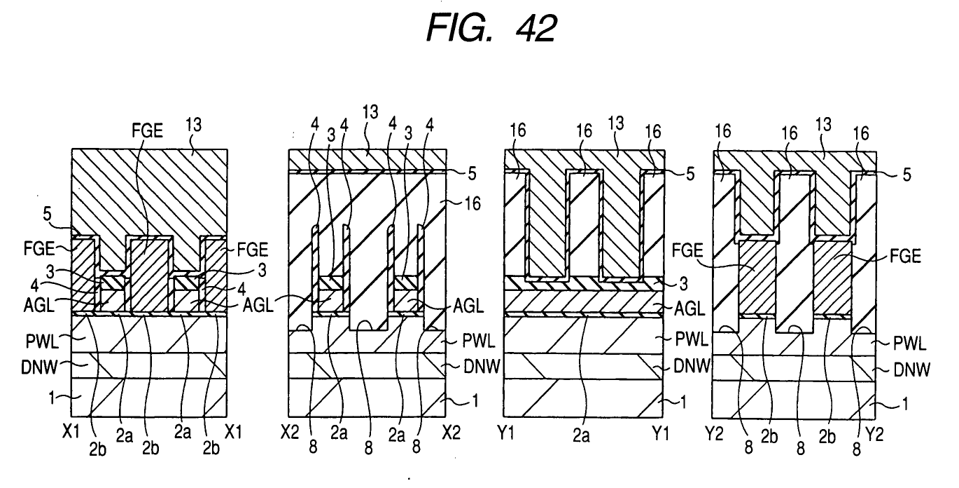

Next, as shown in FIG. 42, after the interpoly dielectric film 5, the conductive film 13 to fabricate the word line are deposited, in order, from the underlayer the same as the aforementioned first embodiment, on the main surface of the substrate 1 (semiconductor wafer); the conductive film 13 is removed by a CMP technique or by etchback until the upper part of the insulator film 16 is exposed. As a result, the word line WL (control gate electrode CGE) lying along the first direction Y shown in FIG. 2 is formed in the groove between the adjacent insulator films 16. The space between the adjacent word lines is insulated by the insulator film 16. Moreover, since the floating gate electrodes FGE are separated in each memory cell MC in the step shown in FIG. 36 in the second embodiment, the one-step process is not necessary when the word line is patterned. Afterwards, although it is not shown in the figure, the contact holes to reach the word line WL, the p-well PWL, the assist gate wiring AGL and the contact holes for power supply to the inversion layer which will be the source line/drain line located outside of the memory array are formed after depositing the insulator film. Then, a metallic film is deposited and patterned to be a circuit to complete the flash memory.

In the memory cell of a flash memory fabricated by using the above-mentioned process, the height of the main surface of the substrate 1 (first main surface section) at the region between the adjacent word lines and the adjacent assist gate wiring AGL is lower than the height of the main surface of the substrate 1 (second main surface section) underneath the assist gate electrode AGL and the main surface of the substrate 1 (third main surface section) underneath the floating gate electrode. Therefore, the same as the first embodiment, a leakage current flowing between the source line SL/drain line DL in the case of the data reading and programming operations can be reduced. As a result, miniaturization of the memory cell MC became possible.

### Third Embodiment

A nonvolatile semiconductor memory device described in this third embodiment is, for instance, a 1 Gb (gigabit) AND type flash memory having a local data line by a diffusion layer and an assist gate structure used for a storage medium of, for instance, the aforementioned various portable devices, information devices and telecommunications devices.

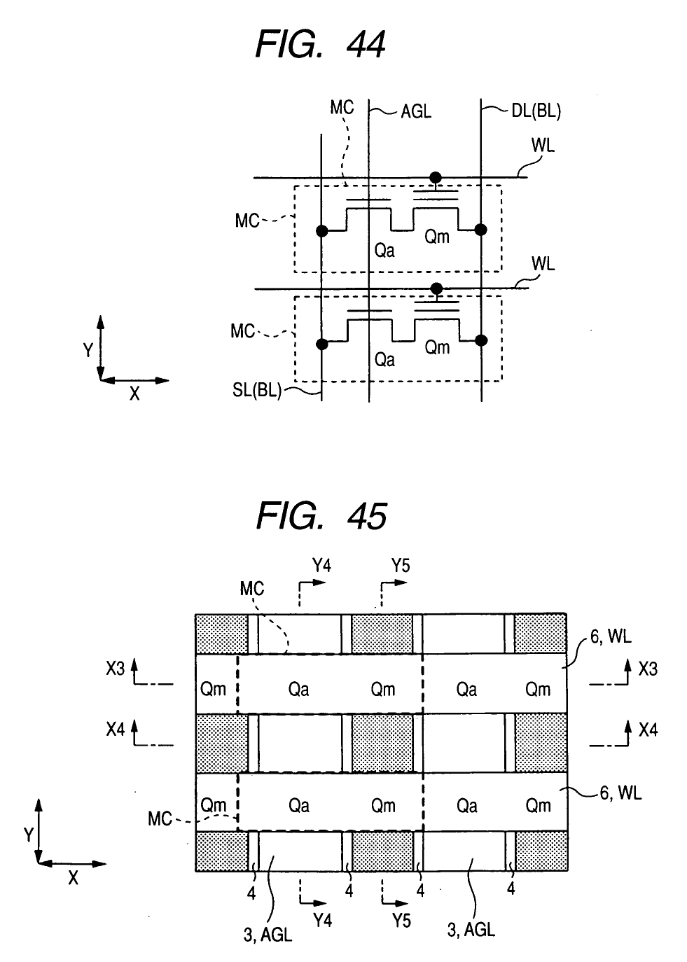

FIG. 44 is a main circuit drawing illustrating a memory array of a flash memory described in the first embodiment. In this flash memory, a plurality of memory cells MC are connected in parallel between the drain line DL to form the local data line BL and the source line SL to form the local data line BL. The memory cell MC has an AG•MISQa and a memory MISQm. AG•MISQa and the memory MISQm are connected in series between the drain line DL and the source line SL. The assist gate electrode (first electrode) of the AG•MISQa consists of a part of the assist gate wiring (first electrode) AGL. A plurality of assist gate electrodes of the AG•MISQa arranged along the first direction Y shown in FIG. 44 are connected to one assist gate wiring AGL. On the other hand, the control gate electrode of the memory MISQm consists of a part of the word line WL. A plurality of control gate electrodes of the memory MISQm arranged along the second direction X shown in FIG. 44 are connected to one word line WL. The memory MISQm has a floating gate electrode. A plurality of such memory cells MC are arranged in the memory array like a matrix.

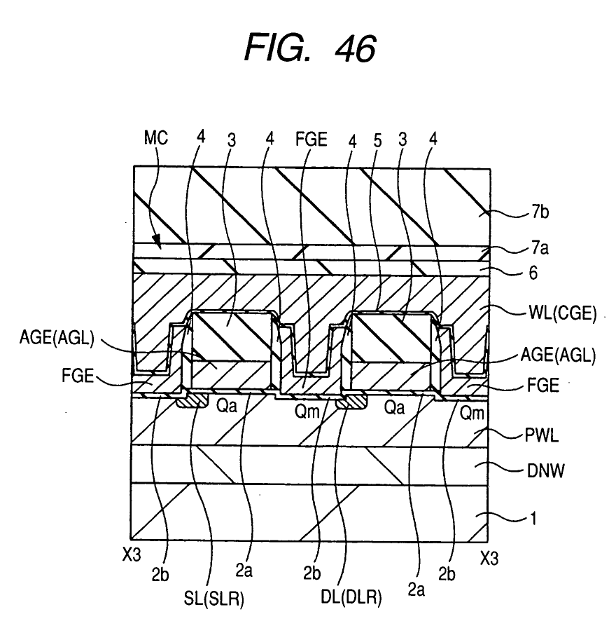

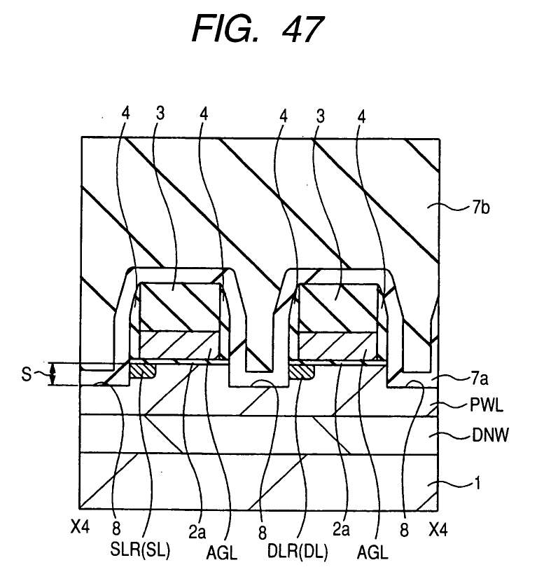

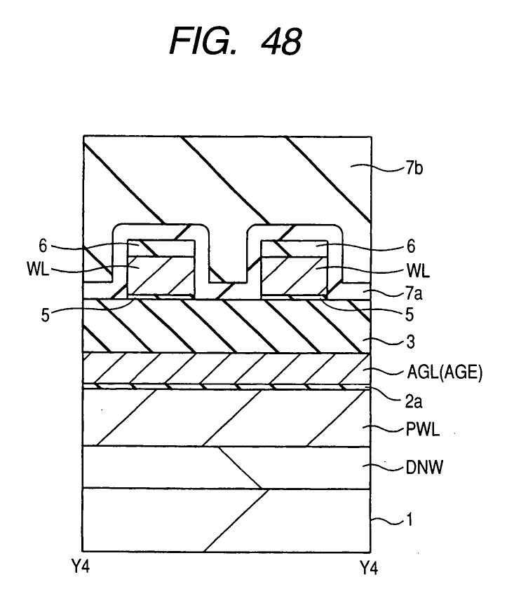

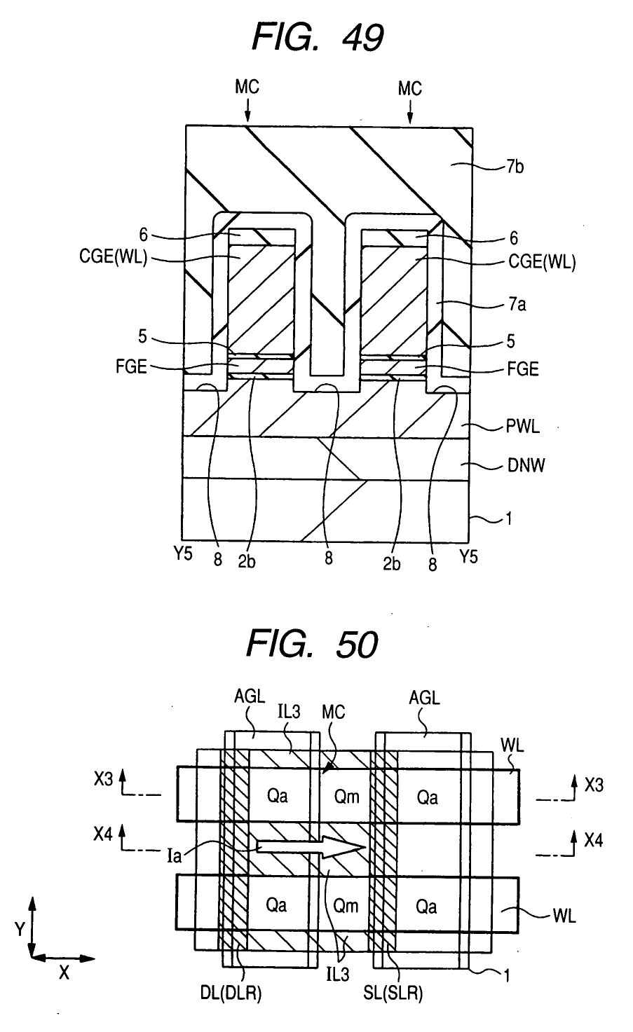

FIG. 45 is a main plane drawing illustrating a memory array shown in FIG. 44, while a flash memory is not on operation, FIG. 46 a cross sectional drawing at the positions of line X3-X3 shown in FIG. 45, FIG. 47 a cross sectional drawing at the positions of line X4-X4 shown in FIG. 2, FIG. 48 a cross sectional drawing at the positions of line Y4-Y4 shown in FIG. 45, FIG. 49 a cross sectional drawing at the positions of line Y5-Y5 shown in FIG. 45. FIG. 45 is a plane drawing, but dotted shading is applied on the junction isolation regions (active region) surrounded by the assist gate wiring AGL and the word line WL to make the drawing easy to view.

In the third embodiment, the aforementioned drain line DL and source line SL consist of the n-type semiconductor regions (diffusion layer) DLR and SLR formed on a p-well PWL. n-type semiconductor regions DLR and SLR are formed by introducing, for instance, phosphorus (P) or (As) into the p-well PWL and consist of band-shaped patterns lying along the first direction Y in FIG. 45. The aforementioned memory cell MC is arranged at the space between the aforementioned adjacent n-type semiconductor regions DLR and SLR, and at the section in which the aforementioned word lines WL are stacked flat. The alignment of the memory cell MC is assumed to be a so-called virtual ground type, for instance, in which the adjacent n-type semiconductor regions DLR and SLR for the drain line DL and the source line SL are shared with each other.

The assist gate electrode AGE of the AG•MISQa in the aforementioned memory cell MC has the function to control or prevent the interference between the memory cells MC. The material and arrangement of the assist gate wiring AGL are the same as the aforementioned first and second embodiments. The floating gate electrode FGE of the above-mentioned memory MISQm is an electrode for storing charge which contributes to information storage, the same as the aforementioned first embodiment. The material, arrangement and insulation condition of the floating gate electrode FGE are the same as the aforementioned first and second embodiments, but the cross-sectional shape of the floating gate FGE is formed in a U-shape in the third embodiment. The material and arrangement of the aforementioned word line WL and the control gate electrode CGE consisting of a part of it are also the same as the aforementioned first and second embodiments. Even in the third embodiment, the concave portion 8 is formed at the junction isolation region (the dot-shaded region in FIG. 45) which is located between the adjacent assist gate wirings AGL and between the adjacent word lines WL, the same as the aforementioned first and second embodiments, and the insulator film 7a is embedded in the concave portion 8. The relationship between the height of the first main surface section of the substrate 1 underneath the assist gate wiring AGL, the height of the third main surface section of the substrate 1 underneath the floating gate electrode FGE, and the height of the second main surface section of the substrate 1 at the aforementioned junction isolation region (that is, the bottom of the concave portion 8) is the same as that of the first embodiment, in which the abovementioned first main surface section is formed to be highest and the abovementioned second main surface part is formed to be lowest.

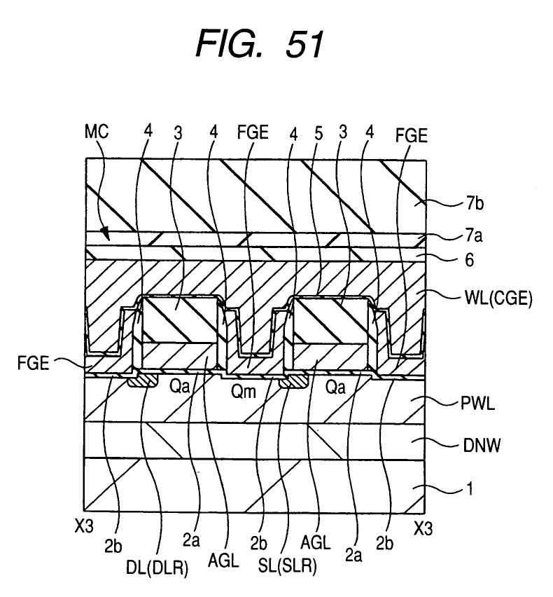

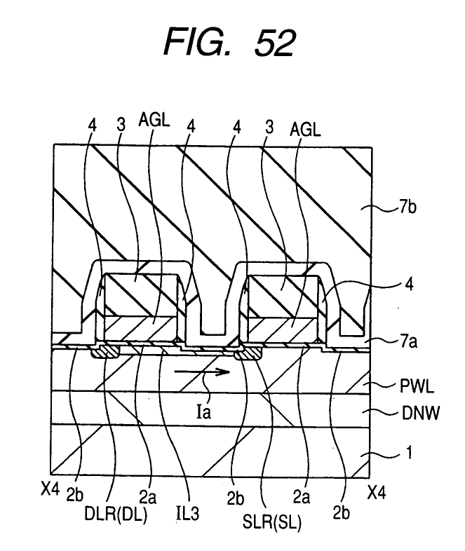

In the case of the third embodiment, as mentioned above, the assist gate wiring AGL and the floating gate electrode FGE are arranged between the n-type semiconductor region SLR for the source line SL and the n-type semiconductor region DLR for the drain line DL, and the distance of the source line SL and the drain line DL is longer than that of the aforementioned first embodiment. Therefore, it appears that a problem caused by a leakage current in the aforementioned junction isolation region never arises. However, the problem of leakage current actually arises in the aforementioned junction isolation region although it is smaller than the case of the configuration described in the above-mentioned first embodiment. FIG. 50 is a main plane drawing illustrating a memory array of a 1 Gb AND type flash memory investigated by the inventors, FIG. 51 a cross-sectional drawing at the position of line X3-X3 of FIG. 50 in the case of programming and reading operations, and FIG. 52 a cross-sectional drawing at the position of line X4-X4 of FIG. 50 in the case of programming and reading operations. In FIG. 50, the semiconductor regions SLR and DLR and the inversion layer IL3 are shaded to make the drawing easy to view.

In FIGS. 50 to 52, since the first main surface section of the substrate 1 at the junction isolation region surrounded by the assist gate wiring AGL and the word line WL and the third main surface section of the substrate 1, to which the floating gate electrode FGE is facing are etched by the removal process of the etching damage layer explained in the aforementioned first embodiment, the heights of the first main surface section and the third main surface section are slightly lower then the second main surface section of the substrate 1 to which the assist gate wiring AGL is facing. However, there is no deep concavity like the aforementioned concave portion 8. Besides, it is the same as the one described in FIGS. 45 to 49, and n-type semiconductor regions SLR and DLR formed on the substrate 1 are used as the source line SL and the drain line DL in the case of programming and reading operations as mentioned above. In this configuration, as described above, the assist gate wiring AGL and the floating gate electrode CGE are arranged between the n-type semiconductor region SLR for the source line SL and the n-type semiconductor region DLR for the drain line DL, so that both are arranged separated. However, a desired voltage is applied to the assist gate wiring AGL to form the inversion layer IL3 on the substrate 1 to which the assist gate wiring AGL is facing in the case of reading and programming operations, and the inversion layer IL3 grows not only right underneath the assist gate wiring AGL but also outside (both sides of the second direction X). Therefore, although it looks like there is enough of a distance between the n-type semiconductor region SLR for the source line SL and the n-type semiconductor region DLR for the drain line DL during the inoperative mode, the distance between the n-type semiconductor region SLR for the source line SL and the n-type semiconductor region DLR for the drain line DL approaches the inversion layer IL3 during operation, so that a problem arises such that a leakage current Ia shown as an arrow flows in the junction isolation region which is surrounded by the assist gate wiring AGL and the word line WL and on which any gate electrode does not exist.

Then, in the third embodiment, as described in FIGS. 45 to 49, the concave portion 8 is formed in at least one part of the junction isolation region surrounded by the assist gate wiring AGL and the word line WL on the main surface of the substrate 1. Accordingly, it is possible to control the leakage current flowing between the drain line DL/source line SL at the junction isolation region, resulting in the leakage current between the data lines being reduced. Therefore, bit defects of flash memory can be reduced and the yield of flash memory can be improved. Moreover, the number of memory cells MC to connect to one data line can be increased and the area of the semiconductor chip can be reduced, resulting in progress in the size reduction of flash memory. Furthermore, the channel length underneath the floating gate electrode FGE can be reduced and the size of the memory cell MC can be reduced, resulting in the capacity of the memory chip being increased and progress in the size reduction of the semiconductor chip.

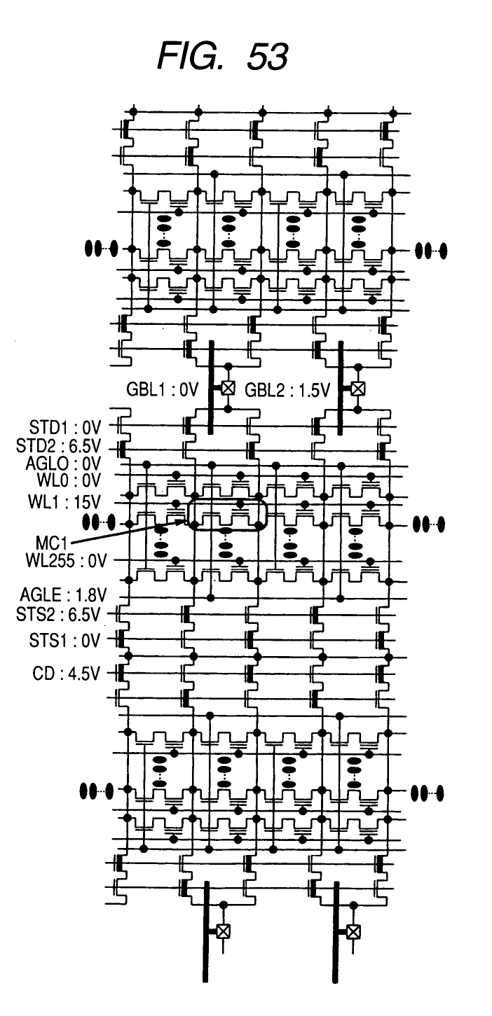

Next, the operation examples of flash memory of the first embodiment are explained by using FIGS. 53 to 55. FIGS. 53 to 55 are main circuit drawings illustrating an example in the case of reading, erasing, and programming operations, respectively. The symbols GBL1 and GBL2 designate the global data lines, CD the common drain, STD the selected MIS (drain line DL side), STS the selected MIS (source line SL side), AGLO the assist gate wiring of AG•MIS (odd side), AGLE the assist gate wiring of Ag•MIS (even side), MC1 the selected memory cell, and WL0 to WL255 the word lines, respectively.

A hot electron injection technique is adapted for the data programming technique by constant charge injection programming. That is, the charge electrified in the source line SL flows as a fixed channel current and is written in the floating gate electrode FGL (source side hot electron injection method). As a result, efficient programming is made possible with high-speed and low current. As shown in FIG. 53, programming to the selected memory cell MC is performed by using the source side hot electron technique, in which voltages of, for instance, about 15 V, about 4.5 V, and about 1.8 V are applied to the selected word line, the selected data line, and to the assist gate wiring AGLE, respectively. By applying the voltages as mentioned above, the channel underneath the assist gate electrode AGE of the selected memory cell MC1 is weekly reversed, the channel underneath the floating gate FGE is completely depleted, and a large potential drop occurs at the boundary of the assist gate electrode AGE and the floating gate electrode FGE, thereby, the channel transverse electric field at the same boundary is increased and hot electrons are efficiently created.

In the first embodiment, as mentioned above, since the leakage current flowing between the drain line DL and the source line SL can be reduced, charging of the drain line DL side of the selected memory cell MC1 can be done very well. Therefore, the programming characteristics can be improved. While programming data to the selected memory cell MC1, another assist gate wiring AGLO is set at, for instance, 0 V and the channel formation at the non-selected memory cell MC is controlled. Specifically, the assist gate electrode AGO functions not only as the programming assist gate, but also as the field isolation. As a result, trench isolation is not necessary for the memory array at the main surface of the substrate 1, resulting in a reduction in the pitch between the data lines being possible.

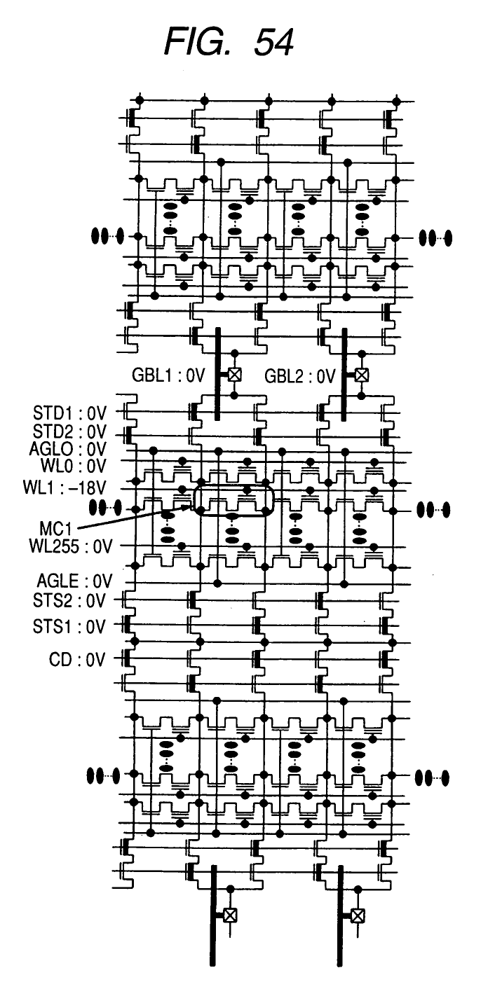

As shown in FIG. 54, data erasing is performed by injecting the charge stored in the floating gate electrode FGE to the substrate 1 by F-N (Fowlor Nordheim) tunnel-emission in which a negative voltage is applied (for instance, about −18 V) to the selected word line WL, and the assist gate wirings AGLO and AGLE are controlled to be, for instance, 0 V.

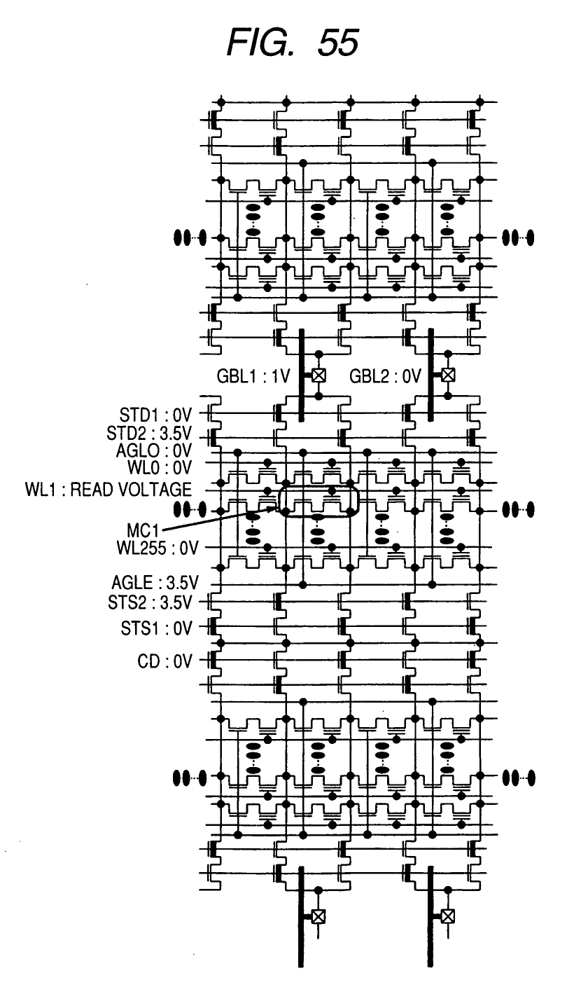

As shown in FIG. 55, data reading is performed by a channel current flowing from the drain line DL to the source line SL, in which a reading voltage is applied to the selected word line WL1 and the voltages applied to the selected data line are, for instance, about 1 v, to the assist gate wiring AGLO, for instance, about 0 V, and to the assist gate wiring AGLE, for instance, about 3.5 V. In the third embodiment, since the leakage current flowing between the drain line DL and the source line SL can be reduced as mentioned above, data reading of the selected memory cell MC1 can be done very well. And the power consumption can be decreased.

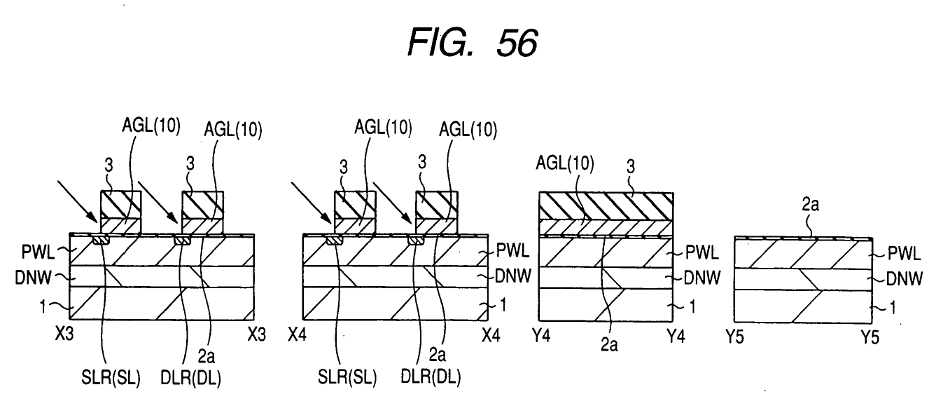

Next, FIGS. 56 to 59 are examples of a manufacturing method of a flash memory of the third embodiment. FIGS. 56 to 59 show the cross-sectional drawings corresponding to the positions of line X3-X3, line X4-X4, line Y4-Y4, and line Y5-Y5 in FIG. 45 in a manufacturing process of a flash memory.

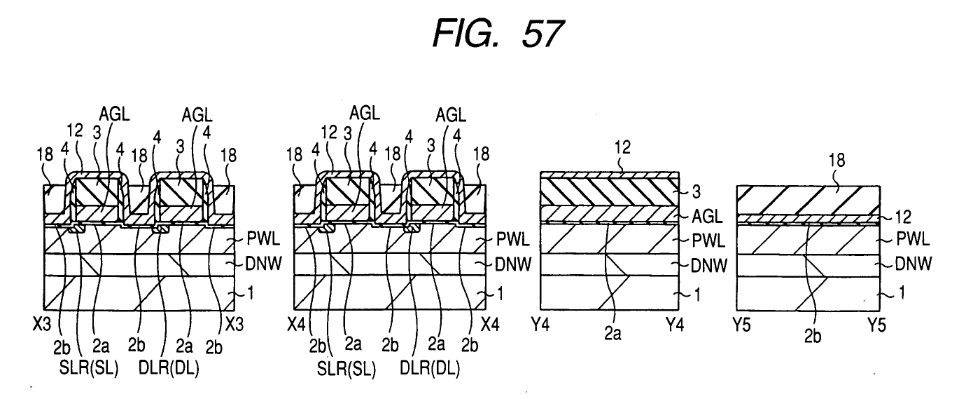

First, after passing the same manufacturing process described using FIG. 19 of the first embodiment, as shown in FIG. 56, a plurality of assist gate wirings AGL and cap insulators 3 are patterned on the gate insulator film 2a on the main surface of the substrate 1 (semiconductor wafer) using a dry etching technique, which is the same as the first embodiment. Next, for instance, phosphorus (P) or arsenic (As) is introduced by using an ion injection technique from the direction inclined against the main surface of the substrate 1, thereby, n-type semiconductor regions DLR and SLR for the drain line DL and source line SL are formed at the vicinity of one edge part of the cross direction (short direction, the second direction X in FIG. 44) of the assist gate wiring AGL so that the one part becomes embedded in the substrate 1 underneath the assist gate wiring AGL. Then, after depositing an insulator film composed of, for instance, silicon oxide on the main surface of the substrate 1 by a CVD technique, the sidewall 4 is formed on the sidewall of the assist gate wiring AGL and the cap insulator film 3 by performing etchback on the film using an anisotropic dry etching technique as shown in FIG. 57. At this time, the gate insulator film 2a on the main surface of the substrate 1 at the junction isolation region is also removed. Then, a removal treatment is performed on the etching damage layer the same as the aforementioned first embodiment. As a result, the main surface of the substrate 1 at the aforementioned junction isolation region is slightly cut away, resulting in it being slightly lower than the main surface of the substrate 1 to which the assist gate wiring AGL is facing. Afterwards, the same as the aforementioned first embodiment, the gate insulator film 2b is formed on the main surface of the substrate 1 at the junction isolation region.

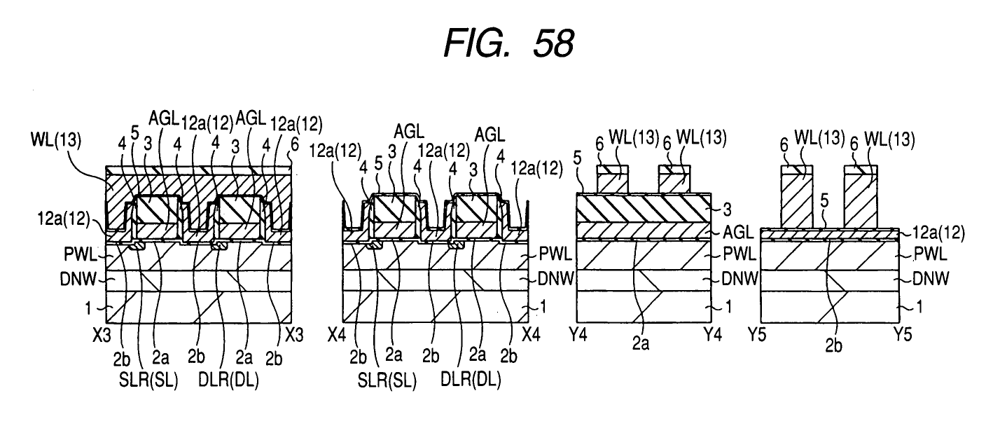

Next, after the conductive film 12 composed of, for instance, low-resistance polysilicon is deposited on the main surface of the substrate 1 (semiconductor wafer) by a CVD (Chemical Vapor Deposition) technique, etc., the insulator film 18 composed of, for instance, low-resistance polysilicon is deposited on the main surface of the substrate 1 by a CVD technique, etc. and etchback is performed to leave the insulator film 18 between the adjacent assist gate wirings AGL using an anisotropic dry etching treatment, etc. Then, as shown in FIG. 58, the conductive pattern 12a to fabricate the floating gate electrode between the adjacent assist gate wirings AGL is formed self-aligned against the assist gate wirings AGL by removing the conductive film 12 exposed from the etching mask, which is the residual insulator film 18, by using an etching technique. Afterwards, the insulator film 18 is selectively removed by etching prior to the interpoly dielectric film 5 being deposited on the main surface of the substrate 1 (semiconductor wafer), the same as the first embodiment. Next, the same as the first embodiment, after the conductive film 13 to fabricate the word line is deposited on the insulator film 5, the insulator film 6 composed of, for instance, silicon oxide is formed thereon by a CVD technique, etc. Then, after patterning the insulator film 6 by a dry etching treatment, the conductive film 13 exposed from the pattern of the insulator film 6 is removed by a dry etching treatment using the patterned film as an etching mask to form the word line WL consisting of the conductive film 13.

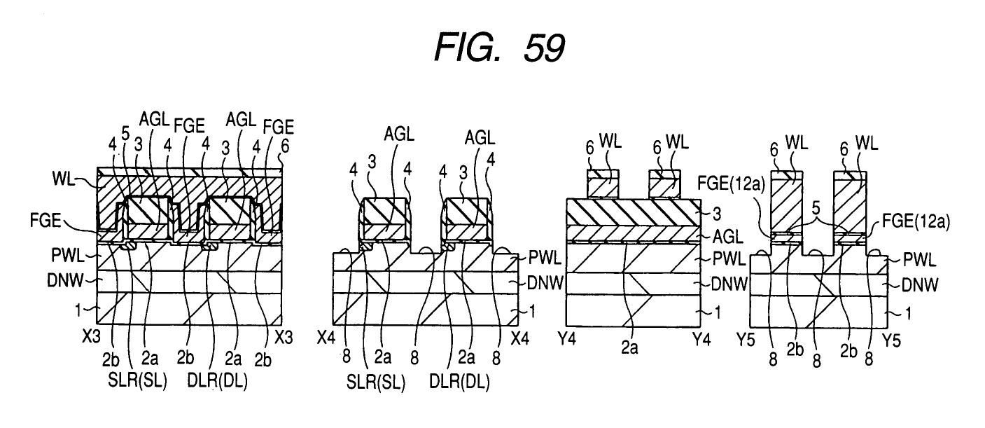

Next, as shown in FIG. 59, the insulator film 5 and the conductive pattern 12a to fabricate the floating gate electrode exposed from the pattern of the insulator film 6, which works as an etching mask, is removed by a dry-etching technique, thereby, the floating gate electrode FGE consisting of the conductive pattern 12a is formed self-aligned against the word line WL. In the third embodiment using the pattern of insulator film 6, the cap insulator film 3, and the sidewall 4 as an etching mask, the section of the gate insulator film 2b and the substrate 1 at the junction isolation region exposed from the etching mask is etched. As a result, the concave portion 8 is formed to be the first main surface section of the substrate 1 at the aforementioned junction isolation region, lower than the second main surface section of the substrate 1 underneath the assist gate wiring AGL. Therefore, the same as the aforementioned first embodiment, a leakage current between the data lines can be reduced as mentioned above. Moreover, the area of the memory region never increases even if the concave portion 8 is formed and the defect can be reduced because the concave portion 8 can be formed with excellent alignment, resulting in flash memory with high reliability being fabricated with a high yield. The same as the first embodiment, the surface morphology of the concave portion 8 of the substrate 1 may be improved by oxidizing the surface of the substrate 1 using a thermal oxidation technique, etc. after forming the concave portion 8. Additionally, after forming the concave portion 8, impurities such as boron (B) etc. to be an acceptor or oxygen may be injected to the junction isolation region of the substrate 1 by an ion injection technique, etc. Moreover, after forming the concave portion 8 by a dry etching technique, the corners of the bottom part of the concave portion 8 may be rounded by applying slightly a wet etching treatment.

Afterwards, the aforementioned insulator films 7a and 7b are deposited on the main surface of the substrate 1 (semiconductor wafer), in order, from the underlayer by a CVD technique, etc., and the concave portion 8, the space between the adjacent word lines WL and the space between the adjacent assist gate wiring AGL are embedded thereby. Then, the upper surface of the insulator film 7b is planarized by using, for instance, a CMP technique to fabricate a flash memory having memory arrays shown in the aforementioned FIGS. 45 to 49.

This invention is not limited to the above-mentioned embodiments though the invention having been performed by this inventor was concretely described on the basis of the embodiments, and it goes without saying that a variety of modifications are possible within a range in which there is no departure from the essential points.

The above explanation described mainly the case when the present invention developed by the inventors was applied to a single flash memory which is a background application area. However, it is not intended to be construed to limit the scope of the invention, and various applications are possible, for instance, a semiconductor device in which flash memories and logic circuits are provided on the same substrate such as a system LSI (Large Scale Integrated circuit) etc. having flash memories and a single EEPROM (Electrically Erasable Memory), and a semiconductor device in which EEPROM is provided.

The present invention can be applied to the manufacture of a nonvolatile semiconductor memory device.

1. A nonvolatile semiconductor memory device comprising:
a plurality of first gate electrodes provided in mutual alignment over the main surface of a semiconductor substrate,
a plurality of second gate electrodes provided in mutual alignment and intersecting said plurality of first gate electrodes over the main surface of said semiconductor substrate,
wherein, at the main surface of said semiconductor substrate, a first main surface section of said semiconductor substrate in the area in which said plurality of first gate electrodes and said plurality of second gate electrodes are not provided has a part lower than a second main surface section of said semiconductor substrate in the region in which said plurality of first gate electrodes are provided.

2. A nonvolatile semiconductor memory device according to claim 1, wherein the step height between the first main surface section and the second main surface section of the main surface of said semiconductor substrate is 20 nm or more.

3. A nonvolatile semiconductor memory device according to claim 1, wherein a concave portion which indents in a direction intersecting said first main surface section is formed on the first main surface section of said semiconductor substrate.

4. A nonvolatile semiconductor memory device according to claim 3, wherein the length of said concave portion in the direction along said first gate electrode is greater than or equal to the space between adjacent said second gate electrodes.

5. A nonvolatile semiconductor memory device according to claim 3, wherein the length of said concave portion in the direction along said second gate electrode is less than the space between adjacent said first gate electrodes.

6. A nonvolatile semiconductor memory device according to claim 5, wherein said concave portion is arranged such that the each edge part in the direction where said second gate electrode is lying has the same space between adjacent said each first gate electrode.

7. A nonvolatile semiconductor memory device according to claim 3, wherein an insulator film is embedded in said concave portion.

8. A nonvolatile semiconductor memory device according to claim 3 comprising:
an insulator film formed on the space between adjacent said plurality of first gate electrodes and on the space between adjacent said plurality of second gate electrodes,
wherein said insulator film is formed in said concave portion.

9. A nonvolatile semiconductor memory device comprising:
a plurality of first gate electrodes in which each of them is formed through a first gate insulator film over a semiconductor substrate and provided in mutual alignment,
a sidewall insulator film formed on each sidewall of said plurality of first gate electrodes,
a plurality of second gate electrodes in which each of them is formed intersecting said plurality of first gate electrodes over said semiconductor substrate and said plurality of first gate electrodes and provided in mutual alignment,
wherein, at the main surface of said semiconductor substrate, a first main surface section of said semiconductor substrate in the area in which said first gate electrode, said second gate electrode, and said sidewall insulator film are not formed, is lower than a second main surface section of said semiconductor substrate in the area in which said plurality of first gate electrodes is provided.

10. A nonvolatile semiconductor memory device according to claim 9 comprising:
a plurality of third gate electrodes formed under a condition insulating them from said semiconductor substrate, said plurality of first gate electrodes, and said plurality of second gate electrodes, between said plurality of second gate electrodes and the main surface of said semiconductor substrate in the space between adjacent said plurality of first gate electrodes,
wherein, at the main surface of said semiconductor substrate, the third main surface part of said semiconductor substrate to which said plurality of third gate electrodes is facing, is lower than said second main surface and higher than said first main surface.

11. A nonvolatile semiconductor memory device according to claim 10, wherein the step height between the first main -surface section and the second main surface section of the main surface of said semiconductor substrate is 20 nm or more.

12. A nonvolatile semiconductor memory device according to claim 10, wherein a semiconductor region to fabricate a data line is formed in the direction along said plurality of first gate electrodes underneath one edge of the same side of each short direction of said plurality of first gate electrodes on said semiconductor substrate.

13. A nonvolatile semiconductor memory device having a memory array in which there is a plurality of nonvolatile memory cells comprising:
a plurality of first gate electrodes formed through a first gate insulator film over the main surface of a semiconductor substrate in which each of them is arranged along the first direction,
a plurality of second gate electrodes formed over said plurality of first gate electrodes in which each of them is arranged along the second direction intersecting said first direction,
a plurality of third gate electrodes formed through the second gate insulator film on the main surface of said semiconductor substrate in the area between the adjacent said plurality of first gate electrodes in which each of said plurality of second gate electrodes is overlapped, and formed under said plurality of second gate electrodes through the insulator film,
wherein, the height of the main surface of said semiconductor substrate of said memory array is the lowest in the section surrounded by said plurality of first gate electrodes and said plurality of second gate electrodes, and an inversion layer, formed on said semiconductor substrate by applying a voltage to a desired first gate electrode out of said plurality of first gate electrodes, is used as a data line.

14. A nonvolatile semiconductor memory device according to claim 13, wherein a concave portion which indents in the direction intersecting the main surface of said semiconductor substrate is formed on said semiconductor substrate in the area surrounded by said plurality of first gate electrodes and said plurality of second gate electrodes.

15. A nonvolatile semiconductor memory device according to claim 14, wherein the depth of said concave portion is greater than the depth of the inversion layer formed.

16. A nonvolatile semiconductor memory device according to claim 15, wherein the depth of said concave portion is 20 nm or more.

17. A nonvolatile semiconductor memory device according to claim 14, wherein the width of said concave potion in said first direction is greater than or equal to the space between the mutually adjacent said plurality of second gate electrodes.

18. A nonvolatile semiconductor memory device according to claim 14, wherein the width of said concave potion in said second direction is smaller than the space between the mutually adjacent said plurality of first gate electrodes.

19. A nonvolatile semiconductor memory device according to claim 18, wherein said concave potion is arranged such that each edge in said second direction has the same space between adjacent each first gate electrode.

20. A nonvolatile semiconductor memory device according to claim 14, wherein a semiconductor region for fabricating a data line is formed in the direction along said plurality of first gate electrodes under one edge of the same side of each second direction of said plurality of first gate electrodes.

21-37. (canceled)
